(19) United States
(12) Patent Application Publication
(10) Pub. No.: US 2026/0018554 A1
(43) Pub. Date: Jan. 15, 2026

(54) SEMICONDUCTOR PACKAGE

(71) Applicant: SAMSUNG ELECTRONICS CO., LTD., Suwon-si (KR)

(72) Inventor: Takuya Futatsuyama, Suwon-si (KR)

(21) Appl. No.: 19/199,074

(22) Filed: May 5, 2025

(30) Foreign Application Priority Data
Jul. 15, 2024 (KR) 10-2024-0093332

(51) Int. Cl. H01L 23/00; H01L 23/31; H01L 25/07

(52) U.S. Cl. CPC H01L 24/32; H01L 23/3135; H01L 25/074; H01L 2224/32145; H01L 2224/32227; H01L 2225/06562

(57) ABSTRACT

An example semiconductor package includes a package substrate including a first upper connection pad and a second upper connection pad on a top surface of the package substrate, a first semiconductor chip stack including a plurality of first semiconductor chips and a first chip pad, a second semiconductor chip stack including a second chip pad and a plurality of second semiconductor chips stacked in a step-like shape on the first semiconductor chip stack, a first conductive pattern extending on the first semiconductor chip and the package substrate, a first cover insulation layer covering at least a portion of the first conductive pattern, a first encapsulation member surrounding the first semiconductor chip stack and the first conductive pattern, and a second conductive pattern extending along the second semiconductor chip, the first encapsulation member, and the package substrate.

### CROSS-REFERENCE TO RELATED APPLICATION

This application claims priority under 35 U.S.C. § 119 to Korean Patent Application No. 10-2024-0093332, filed on Jul. 15, 2024, in the Korean Intellectual Property Office, the disclosure of which is incorporated by reference herein in its entirety.

### BACKGROUND

With the rapid development of the electronics industry and demands of users, electronic devices are becoming increasingly smaller and lighter, and accordingly, the semiconductor devices, which are the core components of electronic devices, are desired to be highly integrated and have larger capacities. Therefore, semiconductor packages including a plurality of semiconductor chips are being developed to achieve large capacity. As the demand for semiconductor devices with larger capacity increases, semiconductor packages are desired to include a plurality of semiconductor chips being stacked.

In some example semiconductor packages a plurality of semiconductor chips are stacked and electrical input/output is established between the plurality of semiconductor chips and a package substrate through wire bonding. Due to wire bonding of the plurality of stacked semiconductor chips, a semiconductor package becomes thicker and the manufacturing process thereof becomes more complex. To resolve the problems, a method of connecting stacked semiconductor chips to a package substrate through wires formed through patterning rather than wire bonding is desired.

### SUMMARY

The present disclosure relates to connection of a package substrate and a plurality of semiconductor chip stacks stacked in a zig-zag shape through a conductive pattern formed by patterning.

In addition, the technical goals to be achieved by the present disclosure are not limited to the technical goals mentioned above, and other technical goals may be clearly understood by one of ordinary skill in the art from the following descriptions.

In some implementations, a semiconductor package includes a package substrate having a first upper connection pad and a second upper connection pad provided on a top surface of the package substrate, a first semiconductor chip stack including a plurality of first semiconductor chips stacked in a step-like shape on the package substrate and a first chip pad provided on a top surface of a first semiconductor chip, a second semiconductor chip stack including a plurality of second semiconductor chips stacked in a step-like shape on the first semiconductor chip stack and a second chip pad provided on a top surface of a second semiconductor chip and positioned closer to the second upper connection pad than to the first upper connection pad, a first conductive pattern extending along the top surface of the first semiconductor chip, side surfaces of the first semiconductor chip, and the top surface of the package substrate and connected to the first chip pad and the first upper connection pad, a first cover insulation layer provided on the package substrate and covering at least a portion of the first conductive pattern, a first encapsulation member surrounding the first semiconductor chip stack and the first conductive pattern on the top surface of the package substrate, and a second conductive pattern extending along the top surface of the second semiconductor chip, side surfaces of the second semiconductor chip, side surfaces of the first encapsulation member, and the top surface of the package substrate and connected to the second chip pad and the second upper connection pad.

In some implementations, a semiconductor package includes a package substrate having a first upper connection pad and a second upper connection pad provided on a top surface of the package substrate, a first stacked chip assembly including a plurality of first semiconductor chips stacked in a step-like shape on the package substrate, a first chip pad provided on a top surface of each of the plurality of first semiconductor chips to be adjacent to a first chip edge of each of the plurality of first semiconductor chips, and a first conductive pattern, a second stacked chip assembly including a plurality of second semiconductor chips stacked in a step-like shape on the first stacked chip assembly, a second chip pad provided on a top surface of each of the plurality of second semiconductor chips to be adjacent to a second chip edge of each of the plurality of second semiconductor chips, and a second conductive pattern, and a first encapsulation member surrounding the first stacked chip assembly, wherein the first conductive pattern is provided along top surfaces and side surfaces of the plurality of first semiconductor chips and is connected to at least one of first chip pads and at least one of first upper connection pad, the second conductive pattern is provided along the top surfaces and the side surfaces of the plurality of first semiconductor chips and a surface of the first encapsulation member and is connected to at least one of second chip pads and at least one of second upper connection pads, and a first cover insulation layer covering the first conductive pattern provided on the top surface of the package substrate is provided on the top surface of the package substrate.

In some implementations, a semiconductor package includes a package substrate having a plurality of upper connection pads provided on a top surface of the package substrate; a plurality of semiconductor chip stacks, each stacked in a step-like shape in one direction, wherein the plurality of semiconductor chip stacks are sequentially stacked in an overall zigzag shape as a semiconductor chip stack in a different step-wise direction from a semiconductor chip stack there below is stacked on the semiconductor chip stack there below, a plurality of encapsulation members each surrounding a corresponding semiconductor chip stack from among the plurality of semiconductor chip stacks, on the package substrate, and a plurality of conductive patterns configured to interconnect the plurality of semiconductor chip stacks and corresponding upper connection pads, wherein the plurality of semiconductor chip stacks include a first semiconductor chip stack closest to the package substrate and a second semiconductor chip stack disposed on the first semiconductor chip stack, on the first semiconductor chip stack, the conductive pattern extends along a surface of the semiconductor chip and the top surface of the package substrate, on the second semiconductor chip stack, conductive patterns extend along the surface of the semiconductor chip, a surface of one of the plurality of encapsulation members, and the top surface of the package substrate, respectively, a separating insulation layer is provided between side surfaces of the plurality of semiconductor chips included in the plurality of semiconductor chip stacks and a plurality of corresponding conductive patterns, the plurality of encapsulation members include a first encapsulation member and a second encapsulation member, the first encapsulation member surrounds the first semiconductor chip stack and the second encapsulation member surrounds the first semiconductor chip stack and the first encapsulation member, and a plurality of cover insulation layers respectively covering the plurality of conductive patterns extending on the top surface of the package substrate in semiconductor chip stacks other than an uppermost semiconductor chip stack from among the plurality of semiconductor chip stacks.

### BRIEF DESCRIPTION OF THE DRAWINGS

Implementations of the present disclosure will be more clearly understood from the following detailed description taken in conjunction with the accompanying diagrams.

FIG. 1 is a cross-sectional view of an example of a semiconductor package.

FIG. 2A is an example enlarged cross-sectional view of a portion A of FIG. 1.

FIG. 2B is an example enlarged cross-sectional view of a portion B of FIG. 1.

FIG. 3 is a cross-sectional view of an example of a semiconductor package.

FIG. 4 is a cross-sectional view of an example of a semiconductor package.

FIG. 5 is an example enlarged cross-sectional view of a portion E of FIG. 4.

FIG. 6 is a cross-sectional view of an example of a semiconductor package.

FIGS. 7A, 7B, 7C, 7D, 7E, 7F, 7G, 7H, and 7I are cross-sectional views sequentially showing an example of a process for manufacturing a semiconductor package.

FIGS. 8A, 8B, 8C, 8D, 8E, and 8F are cross-sectional views sequentially showing an example of a process for manufacturing a semiconductor package.

### DETAILED DESCRIPTION

In this specification, a first direction means the X direction, a second direction means the Y direction, and the first direction and the second direction may be perpendicular to each other. A third direction is the Z direction, and the third direction may be perpendicular to each of the first direction and the second direction. A horizontal plane or a plane refers to the XY plane. The top surface of a particular object refers to a surface of the particular object located in the positive third direction, and the bottom surface of a particular object refers to a surface of the particular object located in the negative third direction.

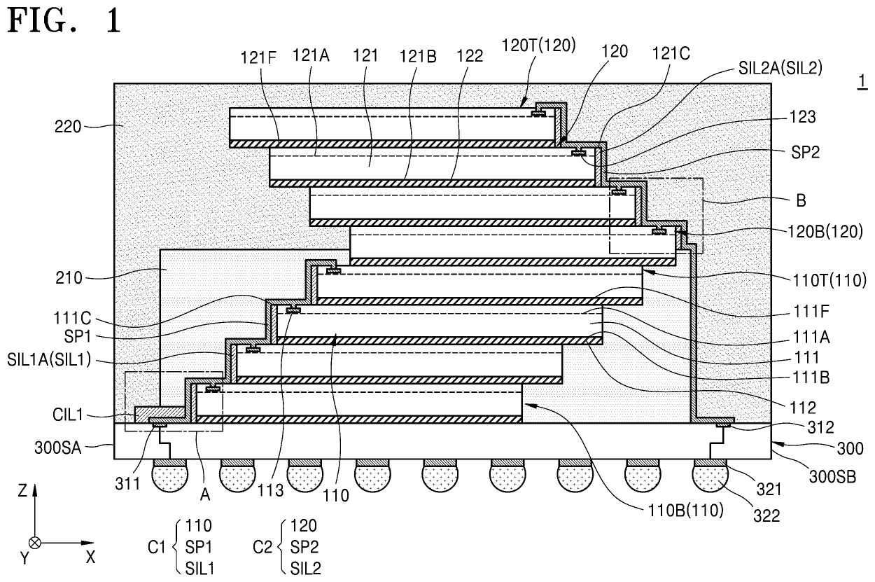

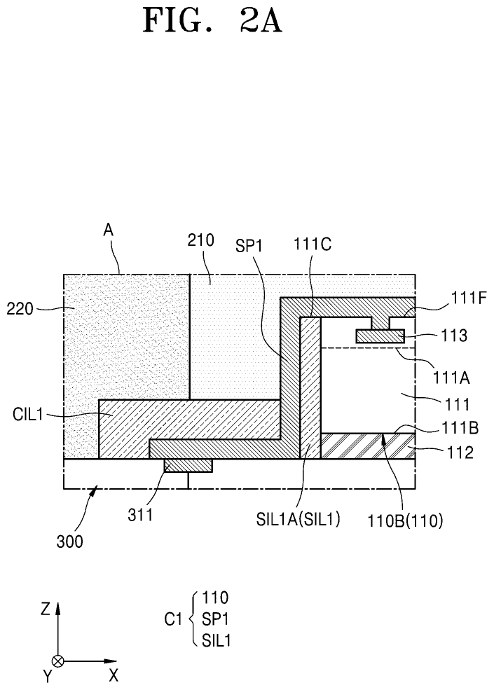

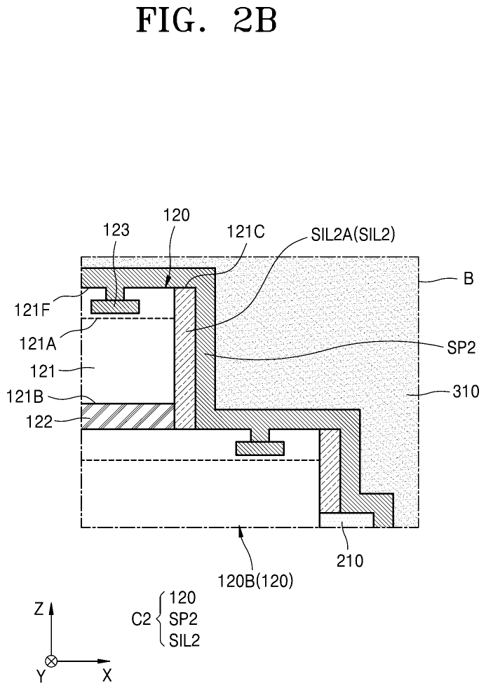

FIG. 1 is a cross-sectional view of an example of a semiconductor package 1. FIG. 2A is an example enlarged cross-sectional view of a portion A of FIG. 1. FIG. 2B is an example enlarged cross-sectional view of a portion B of FIG. 1.

Referring to FIGS. 1, 2A, and 2B, the semiconductor package 1 may include a package substrate 300, a first semiconductor chip stack C1 provided on the package substrate 300 and including a plurality of first semiconductor chips 110, a second semiconductor chip stack C2 provided on the first semiconductor chip stack C1 and including a plurality of second semiconductor chips 120, a first encapsulation member 210, and a second encapsulation member 220. The first semiconductor chip stack C1 may be referred to as the lowermost semiconductor chip stack.

The package substrate 300 may include a first upper connection pad 311 and a second upper connection pad 312 on the top surface of the package substrate 300 and include an external connection pad 321 and an external connection terminal 322, which is provided on the external connection pad 321, on the bottom surface of the package substrate 300. The package substrate 300 may be connected to an external electronic device, such as a printed circuit board (PCB), through the external connection terminal 322. The package substrate 300 may be, for example, a PCB or a redistribution structure.

When the package substrate 300 is a PCB, the package substrate 300 may include a base layer, and the base layer may include a plurality of stacked sub-base layers. The top surface and the bottom surface of the base layer may be covered with a solder resist layer. The first upper connection pad 311, the second upper connection pad 312, and the external connection pad 321 on the bottom surface of the package substrate 300 may not be covered by the solder resist layer and be exposed on the top surface and the bottom surface of the package substrate 300.

In some implementations, the base layer may include at least one material selected from among phenol resin, epoxy resin, and polyimide. For example, the base layer may include at least one material selected from among Frame Retardant 4 (FR4), tetrafunctional epoxy, polyphenylene ether, epoxy/polyphenylene oxide, bismaleimide triazine (BT), cyanate ester, polyimide, and liquid crystal polymer.

When the package substrate 300 is a redistribution structure, the package substrate 300 may include a plurality of redistribution insulation layers and a redistribution pattern provided within the redistribution insulation layers. The redistribution pattern may include a plurality of redistribution line patterns and a plurality of redistribution via patterns. The plurality of redistribution line patterns may be provided between the plurality of redistribution insulation layers, and the plurality of redistribution via patterns may penetrate through the plurality of redistribution insulation layers and interconnect between the plurality of redistribution line patterns.

In some implementations, the redistribution insulation layer may include an insulation material, for example, photo imageable dielectric (PID) resin. In this case, the redistribution insulation layer may further include an inorganic filler. The redistribution pattern may include a conductive material, e.g., Cu, aluminum (Al), silver (Ag), tin (Sn), gold (Au), nickel (Ni), lead (Pb), titanium (Ti), or alloys thereof.

In this specification, the electrical connection between the first upper connection pad 311, the second upper connection pad 312, a third upper connection pad 313, and a fourth upper connection pad 314 of the package substrate 300, which will be described below, and the external connection pad 321 provided on the bottom surface of the package substrate 300 is schematically illustrated.

The first semiconductor chip stack C1 may include the plurality of first semiconductor chips 110, a first conductive pattern SP1, and a first separating insulation layer SIL1. The plurality of first semiconductor chips 110 may each include a first semiconductor substrate 111, a first adhesive film 112, and a first chip pad 113. In this specification, a semiconductor chip stack may be referred to as a semiconductor chip assembly.

The plurality of first semiconductor chips 110 may include two or more first semiconductor chips 110. For example, the plurality of first semiconductor chips 110 may include four first semiconductor chips 110. Alternatively, the plurality of first semiconductor chips 110 may include two, six, or eight first semiconductor chips 110. The drawings of this specification illustrate an example in which a plurality of semiconductor chips include four semiconductor chips, but the number of semiconductor chips included in the plurality of semiconductor chips is not limited thereto.

The plurality of first semiconductor chips 110 may be stacked in a step-like shape. In other words, a first semiconductor chip 110 may be disposed over and offset in a particular direction from the first semiconductor chip 110 located there below. For example, as shown in FIG. 1, the first semiconductor chip 110 may be offset in a positive first direction (+X direction) and disposed directly over the first semiconductor chips 110 there below.

The first chip pad 113 adjacent to a first chip edge 111C may be provided on a portion of the top surface of the first semiconductor chip 110 exposed as the plurality of first semiconductor chips 110 are offset. In other words, the first chip pad 113 may be positioned on the top surface of each exposed first semiconductor chip 110 among the plurality of first semiconductor chips 110 stacked in a step-like shape. The first chip pad 113 may be exposed from a passivation layer provided on the top surface of the first semiconductor chip 110. The first chip pad 113 exposed from the passivation layer may be connected to the first conductive pattern SP1.

In the plurality of first semiconductor chips 110 that are offset and stacked in a step-like shape, the first chip edge 111C may refer to an edge formed by the top surface exposed due to the offset of each first semiconductor chip 110 and a side surface of each first semiconductor chip 110. A second chip edge 121C of the second semiconductor chip 120, a third chip edge 131C of the third semiconductor chip 130, and a fourth chip edge 141C of the fourth semiconductor chip 140 described below may also be referred to in the same manner as the first chip edge 111C of the first semiconductor chip 110.

The first semiconductor chip 110 may include the first semiconductor substrate 111. The first semiconductor substrate 111 may include, for example, silicon (Si). Alternatively, the first semiconductor substrate 111 may include a semiconductor element, such as germanium (Ge), or a compound semiconductor, such as silicon carbide (SiC), gallium arsenide (GaAs), indium arsenide (InAs), and indium phosphide (InP). Alternatively, the first semiconductor substrate 111 may have a silicon-on-insulator (SOI) structure. For example, the first semiconductor substrate 111 may include a buried oxide (BOX) layer. The first semiconductor substrate 111 may include a conductive region, e.g., a well doped with an impurity. The first semiconductor substrate 111 may have various device isolation structures such as a shallow trench isolation (STI) structure. The first semiconductor substrate 111 may have a first active surface 111A and a first inactive surface opposite to the first active surface 111A active surface. The first inactive surface may be referred to as a first substrate back surface 111B.

A semiconductor device including a plurality of individual devices of various types may be formed on the first active surface 111A of the first semiconductor chip 110. The individual devices may include various microelectronic devices, e.g., a metal-oxide-semiconductor field effect transistor (MOSFET) such as a complementary metal-insulator-semiconductor (CMOS) transistor, a floating gate transistor, a system large scale integration (LSI), an image sensor such as a CMOS imaging sensor (CIS), a micro-electro-mechanical system (MEMS), an active device, a passive device, etc.

The plurality of individual devices may be electrically connected to the conductive region of the first semiconductor substrate 111. Also, the individual devices may each be electrically separated from other neighboring individual devices by an insulating film.

For example, the first semiconductor chip 110 may include a plurality of memory semiconductor devices. In some implementations, the memory semiconductor device may be a non-volatile memory semiconductor device such as flash memory, phase-change random access memory (PRAM), magnetoresistive random access memory (MRAM), ferroelectric random access memory (FeRAM), or resistive random access memory (RRAM). The flash memory may be, for example, V-NAND flash memory. In some implementations, the memory semiconductor device may be a volatile memory device such as dynamic random access memory (DRAM) or static random access memory (SRAM).

The first semiconductor chip 110 may include a first substrate front surface 111F and the first substrate back surface 111B. A surface adjacent to the first active surface 111A of the first semiconductor chip 110 may be referred to as the first substrate front surface 111F, and a surface opposite to the first substrate front surface 111F may be referred to as the first substrate back surface 111B. In this specification, a surface facing upward in the vertical direction may be referred to as the top surface, and a surface facing downward in the vertical direction may be referred to as the bottom surface. In other words, the top surface of the first semiconductor chip 110 may be the first substrate front surface 111F, and the bottom surface of the first semiconductor chip 110 may be the first substrate back surface 111B. The first semiconductor chip 110 may be disposed on the package substrate 300 such that the first active surface 111A of the first semiconductor chip 110 is located farther from the package substrate 300 than the first substrate back surface 111B, which is the first inactive surface.

The plurality of first semiconductor chips 110 may include a lowermost first semiconductor chip 110B located closest to the package substrate 300 from among the plurality of first semiconductor chips 110 and an uppermost first semiconductor chip 110T located farthest from the package substrate 300 from among the plurality of first semiconductor chips 110.

The plurality of first semiconductor chips 110 may each include a plurality of first chip pads 113 respectively arranged on the top surfaces of the plurality of first semiconductor chips 110. For example, the plurality of first chip pads 113 may be arranged on first active surfaces 111A of the plurality of first semiconductor chips 110, respectively. The plurality of first semiconductor chips 110 may each be stacked on the package substrate 300 such that the first active surface 111A faces upward, i.e., in a direction away from the package substrate 300. The plurality of first semiconductor chips 110 may each be stacked on the package substrate 300 such that the first inactive surface faces downward, i.e., toward the package substrate 300.

The first adhesive film 112 may be disposed on the bottom surface of each of the plurality of first semiconductor chips 110, and thus the plurality of first semiconductor chips 110 may be attached to structures there below. For example, the first adhesive film 112 may be provided on the bottom surface of the lowermost first semiconductor chip 110B from among the plurality of first semiconductor chips 110, and the first adhesive film 112 may be attached to the package substrate 300. The first adhesive film 112 may be provided between the plurality of first semiconductor chips 110 other than the lowermost first semiconductor chip 110B.

The first separating insulation layer SIL1 may include a first side surface separating insulation layer SIL1A. The first side surface separating insulation layer SIL1A may cover a portion of the side surface of the plurality of first semiconductor chips 110. For example, the first side surface separating insulation layer SIL1A may cover at least a portion of a side surface of the plurality of first semiconductor chips 110 adjacent to the first chip pad 113. Alternatively, at least a portion of a side surface of the plurality of first semiconductor chips 110 facing a first substrate side surface 300SA, which is one of the side surfaces of the package substrate 300, may be covered by the first side surface separating insulation layer SIL1A.

Alternatively, the first side surface separating insulation layer SIL1A may be provided between the first conductive pattern SP1 and the side surfaces of the plurality of first semiconductor chips 110 such that the side surfaces of the first conductive pattern SP1 and the plurality of first semiconductor chips 110 are spaced apart from each other. Therefore, the first side surface separating insulation layer SIL1A may be disposed only on a portion of the side surface of the plurality of first semiconductor chips 110 adjacent to the first conductive pattern SP1 from among the side surfaces of the plurality of first semiconductor chips 110.

The first separating insulation layer SIL1 may include an insulation material. For example, the first separating insulation layer SIL1 may include silicon oxide, silicon nitride, aluminum oxide, zirconium oxide, hafnium oxide, combinations thereof, or similar materials known to one of ordinary skill in the art. In some implementations, the first separating insulation layer SIL1 may include an organic material such as a polyimide, a polymer, and a polyimide silicone, an ultraviolet (UV) ray curable material, a thermosetting liquid crystal polymer, a combination thereof, or similar materials known to one of ordinary skill in the art.

Alternatively, the first separating insulation layer SIL1 may include a polymer film and metal-containing particles dispersed in the polymer film. The polymer film may include various materials, e.g., an epoxy mold compound or parylene. The metal-containing particles may include a metal oxide, a metal nitride, a metal carbide, or a metal sulfide or may be metal particles coated with an insulation material. Various metals may be included in the metal-containing particles, e.g., aluminum, magnesium, iron, manganese, copper, chromium, cobalt, nickel, etc. In some implementations, the first separating insulation layer SIL1 may be formed by using deposition, dispensing, coating, or screen printing techniques.

The constituent materials and the method of forming second to fourth separating insulation layers SIL2, SIL3, and SIL4 and first to third cover insulation layers CIL1, CIL2, and CIL3 to be described below may be substantially identical to the constituent materials and the method of forming the first separating insulation layer SIL1 described above.

The first upper connection pad 311 may be provided on the top surface of the package substrate 300 and laterally spaced from the first semiconductor chip stack C1. For example, when the first semiconductor chip stack C1 is stacked in a step-like shape and the first semiconductor chip 110 located on top of the first semiconductor chip 110 is stacked with an offset in the positive first direction (+X direction), the first upper connection pad 311 may be provided on the top surface of the package substrate 300 and spaced apart from the lowermost first semiconductor chip 110B in the negative first direction (−X direction).

The first chip pad 113 provided on each of the plurality of first semiconductor chips 110 may be connected to the first upper connection pad 311 provided on the top surface of the package substrate 300. The first conductive pattern SP1 may electrically interconnect at least one first chip pad 113 and the first upper connection pad 311 that need to be connected to each other. The first conductive pattern SP1 may include a conductive material, and the conductive material may include, for example, copper (Cu), aluminum (Al), silver (Ag), tin (Sn), gold (Au), nickel (Ni), lead (Pb), titanium (Ti), or an alloy thereof.

The first conductive pattern SP1 may be extended in a straight line on the horizontal plane from the first chip pad 113 of the uppermost first semiconductor chip 110T to the first chip pad 113 of the lowermost first semiconductor chip 110B and connected to the first upper connection pad 311 of the package substrate 300. Alternatively, the first conductive pattern SP1 may extend from the first chip pad 113 of the uppermost first semiconductor chip 110T to the first chip pad 113 of the lowermost first semiconductor chip 110B, but a portion of the extended first conductive pattern SP1 may be bent or slanted to connect the first chip pad 113 of the uppermost first semiconductor chip 110T to the first chip pad 113 of the lowermost first semiconductor chip 110B. Alternatively, a portion of the first conductive pattern SP1 that passed the lowermost first semiconductor chip 110B may be bent or slanted to reach the first upper connection pad 311 and may be electrically connected to the first upper connection pad 311.

A first cover insulation layer CIL1 may cover the first conductive pattern SP1 extending on the package substrate 300 from among first conductive patterns SP1. The first cover insulation layer CIL1 may cover the first conductive pattern SP1 and may be provided on the top surface of the package substrate 300. The first cover insulation layer CIL1 may be in contact with the first side surface separating insulation layer SIL1A. The first cover insulation layer CIL1 may be in contact with at least a portion of the first side surface separating insulation layer SIL1A provided on at least a portion of the side surface of the lowermost first semiconductor chip 110B, and the first conductive pattern SP1 may be provided between the first cover insulation layer CIL1 and the first side surface separating insulation layer SIL1A.

The first conductive pattern SP1 may extend along the top surfaces of the first semiconductor chip 110, the first separating insulation layer SIL1, and the package substrate 300. In other words, the first conductive pattern SP1 may be provided between the top surfaces of the first semiconductor chip 110, the first separating insulation layer SIL1, and the package substrate 300, the first encapsulation member 210, and the first cover insulation layer CIL1.

The first encapsulation member 210 may surround the first semiconductor chip stack C1 on the package substrate 300. For example, the first encapsulation member 210 may surround the plurality of first semiconductor chips 110, the first conductive pattern SP1, and the first separating insulation layer SIL1 on the top surface of the package substrate 300. As shown in FIG. 2A, the first encapsulation member 210 may cover a portion of the first cover insulation layer CIL1. In other words, a portion of the first cover insulation layer CIL1 may protrude from a side surface of the first encapsulation member 210.

The first encapsulation member 210 may be in contact with some of a plurality of second semiconductor chips 120 included in the second semiconductor chip stack C2. Referring to FIG. 1, the first encapsulation member 210 may be in contact with a side surface of a lowermost second semiconductor chip 120B closest to the package substrate 300 from among the plurality of second semiconductor chips 120. Alternatively, the top surface of the first encapsulation member 210 may contact a side surface of the lowermost second semiconductor chip 120B. The first encapsulation member 210 may include, for example, an epoxy molding compound (EMC) or a polymer material.

The vertical level of the top surface of the first encapsulation member 210 may be higher than the vertical level of the highest portion of the first conductive pattern SP1. In other words, the first encapsulation member 210 may cover the first conductive pattern SP1 connected to the uppermost first semiconductor chip 110T, which is the highest portion of the first conductive pattern SP1.

A portion of a second conductive pattern SP2, which will be described below, may be provided on a surface of the first encapsulation member 210. For example, as shown in FIG. 1, the second conductive pattern SP2 may extend along a side surface of the first encapsulation member 210 adjacent to the second upper connection pad 312, and the second conductive pattern SP2 may be connected to the second upper connection pad 312 provided on the package substrate 300.

In some implementations, the semiconductor package 1 may more stably support the second semiconductor chip stack C2 disposed on the first semiconductor chip stack C1 by supporting the first semiconductor chip stack C1 with the first encapsulation member 210 surrounding the first semiconductor chip stack C1. Therefore, the structural reliability in the manufacturing process of the semiconductor package 1 and the structural reliability of a finished semiconductor package 1 may be improved.

The second semiconductor chip stack C2 may include the plurality of second semiconductor chips 120, the second conductive pattern SP2, and a second separating insulation layer SIL2. The plurality of second semiconductor chips 120 may each include a second semiconductor substrate 121, a second adhesive film 122, and a second chip pad 123.

The plurality of second semiconductor chips 120 may include the lowermost second semiconductor chip 120B located closest to the package substrate 300 from among the plurality of second semiconductor chips 120 and an uppermost second semiconductor chip 120T located farthest from the package substrate 300 from among the plurality of second semiconductor chips 120.

The second semiconductor chip stack C2 may be disposed on the first semiconductor chip stack C1. In other words, the lowermost second semiconductor chip 120B of the second semiconductor chip stack C2 may be disposed on the uppermost first semiconductor chip 110T of the first semiconductor chip stack C1, and another second semiconductor chip 120 may be disposed on the lowermost second semiconductor chip 120B.

From among the plurality of second semiconductor chips 120 included in the second semiconductor chip stack C2, the lowermost second semiconductor chip 120B may be arranged with the same offset from the uppermost first semiconductor chip 110T of the first semiconductor chip stack C1 in the direction in which the plurality of first semiconductor chips 110 are offset. For example, as shown in FIG. 1, the lowermost second semiconductor chip 120B may be offset from the uppermost first semiconductor chip 110T in the positive first direction, in which the plurality of first semiconductor chips 110 are offset.

The plurality of second semiconductor chips 120 may be stacked in a step-like shape. In other words, the second semiconductor chip 120 may be disposed over and offset in a particular direction from the second semiconductor chip 120 located there below. For example, as shown in FIG. 1, the second semiconductor chip 120 may be offset in the negative first direction (−X direction) and disposed directly over the second semiconductor chips 120 there below.

The step-wise stacking direction of the plurality of first semiconductor chips 110 may be different from the step-wise stacking direction of the plurality of second semiconductor chips 120. Here, the step-wise stacking direction refers to offset directions of semiconductor chips. For example, since the step-wise stacking direction of the plurality of first semiconductor chips 110 is the positive first direction and the step-wise stacking direction of the plurality of second semiconductor chips 120 is the negative first direction, the step-wise stacking direction of the plurality of first semiconductor chips 110 is different from the step-wise stacking direction of the plurality of second semiconductor chips 120. In FIG. 1, the step-wise stacking direction of the plurality of first semiconductor chips 110 and the step-wise stacking direction of the plurality of second semiconductor chips 120 are opposite to each other.

The shape of the plurality of first semiconductor chips 110 may be a step-like stacking shape ascending in the positive first direction, and the shape of the plurality of second semiconductor chips 120 may be a step-like stacking shape ascending in the negative first direction. The direction in which the plurality of first semiconductor chips 110 are laterally offset may be the positive first direction as described above, and the direction in which the plurality of second semiconductor chips 120 are laterally offset may be the negative first direction as described above. In other words, the step-wise stacking direction of the plurality of first semiconductor chips 110 may be different from the step-wise stacking direction of the plurality of second semiconductor chips 120. In this specification, the overall stacking shape of a plurality of semiconductor chip stacks stacked in opposite or different directions may be referred to as a zig-zag shape.

In other words, each semiconductor chip stack included in a plurality of semiconductor chip stacks is stacked in a one-way step-like shape, and a semiconductor chip stack in a step-wise direction different from that of a lower semiconductor chip stack is sequentially stacked on the lower semiconductor chip stack, and thus the overall stacking shape of the plurality of semiconductor chip stacks may be a zigzag shape. The plurality of semiconductor chip stacks may include the first semiconductor chip stack C1 and the second semiconductor chip stack C2 and a third semiconductor chip stack C3 and a fourth semiconductor chip stack C4 to be described below.

The plurality of second semiconductor chips 120 may include two or more second semiconductor chips 120. For example, the plurality of second semiconductor chips 120 may include four second semiconductor chips 120. Alternatively, the plurality of second semiconductor chips 120 may include two, six, or eight second semiconductor chips 120.

The second chip pad 123 adjacent to the second chip edge 121C may be provided on a portion of the top surface of the second semiconductor chip 120 exposed due to the offset of the plurality of second semiconductor chips 120. In other words, the second chip pad 123 may be positioned on the top surface of each exposed second semiconductor chip 120 of the plurality of second semiconductor chips 120 stacked in a step-like shape. The second chip pad 123 may be exposed from a passivation layer provided on the top surface of the second semiconductor chip 120. The second chip pad 123 exposed from the passivation layer may be connected to the second conductive pattern SP2.

The second semiconductor chip 120 may include the second semiconductor substrate 121. The second semiconductor substrate 121 may include, for example, silicon (Si). A semiconductor device including a plurality of individual devices of various types may be formed on the active surface of the second semiconductor chip 120. For example, the second semiconductor chip 120 may be a memory semiconductor chip. The second semiconductor chip 120 may include a second substrate front surface 121F and a second substrate back surface 121B.

The second adhesive film 122 may be attached to the bottom surface of each of the plurality of second semiconductor chips 120, and thus the plurality of second semiconductor chips 120 may be attached to structures there below. For example, the second adhesive film 122 may be provided on the bottom surface of the lowermost second semiconductor chip 120B from among the plurality of second semiconductor chips 120, and the second adhesive film 122 may be attached to the uppermost first semiconductor chip 110T. The second adhesive film 122 may be provided between the plurality of second semiconductor chips 120 other than the lowermost second semiconductor chip 120B.

Detailed descriptions of the second semiconductor chip 120 and the second semiconductor substrate 121 may be identical to those of the first semiconductor chip 110 and the first semiconductor substrate 111 given above.

The second separating insulation layer SIL2 may cover a portion of the side surface of the plurality of second semiconductor chips 120. For example, a second side surface separating insulation layer SIL2A may cover at least a portion of a side surface of the plurality of second semiconductor chips 120 adjacent to the second chip pad 123. Alternatively, at least a portion of a side surface of the plurality of second semiconductor chips 120 facing a second substrate side surface 300SB, which is one of the side surfaces of the package substrate 300, may be covered by the second side surface separating insulation layer SIL2A. The first side surface separating insulation layer SIL1A may be included in the first separating insulation layer SIL1.

Alternatively, the second side surface separating insulation layer SIL2A may be provided between the second conductive pattern SP2 and the side surfaces of the plurality of second semiconductor chips 120 such that the side surfaces of the second conductive pattern SP2 and the plurality of second semiconductor chips 120 are spaced apart from each other. Therefore, the second side surface separating insulation layer SIL2A may be disposed only on a portion of the side surface of the plurality of second semiconductor chips 120 adjacent to the second conductive pattern SP2 from among the side surfaces of the plurality of second semiconductor chips 120.

As shown in FIG. 2B, the vertical height of the second side surface separating insulation layer SIL2A disposed on the side surface of the lowermost second semiconductor chip 120B may be less than the vertical height of the second side surface separating insulation layer SIL2A arranged on the side surface of another second semiconductor chip 120. The top surface of the first encapsulation member 210 may contact a side surface of the lowermost second semiconductor chip 120B. In other words, a portion of the side surface of the lowermost second semiconductor chip 120B may contact the first encapsulation member 210. The second side surface separating insulation layer SIL2A may be provided on the remaining side surface of the lowermost second semiconductor chip 120B, which is not in contact with the first encapsulation member 210.

The second separating insulation layer SIL2 may include an insulation material. For example, the second separating insulation layer SIL2 may include a polymer film and metal-containing particles dispersed in the polymer film. Detailed descriptions of the constituent materials of the second separating insulation layer SIL2 may be substantially identical to those of the first separating insulation layer SIL1.

The second upper connection pad 312 may be provided on the top surface of the package substrate 300 and laterally spaced from a first encapsulation member 310. The second upper connection pad 312 may be provided in a direction different from the direction in which the first upper connection pad 311 is located with respect to the first semiconductor chip stack C1. For example, the first upper connection pad 311 may be disposed on the package substrate 300 in the negative first direction with respect to the first semiconductor chip stack C1, and the second upper connection pad 312 may be disposed on the package substrate 300 in the positive first direction with respect to the first semiconductor chip stack C1. In other words, in FIG. 1, the second upper connection pad 312 may be provided in a direction away from the direction in which the first upper connection pad 311 is located with respect to the first semiconductor chip stack C1.

Since the step-wise stacking direction of the first semiconductor chip 110 of the first semiconductor chip stack C1 described above and the step-wise stacking direction of the second semiconductor chip 120 of the second semiconductor chip stack C2 are opposite to each other, the position of the first upper connection pad 311 connected to the first semiconductor chip stack C1 through the first conductive pattern SP1 and the position of the second upper connection pad 312 connected to the second semiconductor chip stack C2 through the second conductive pattern SP2 are opposite to each other.

Through the second conductive pattern SP2, the second chip pad 123 provided on each of the plurality of second semiconductor chips 120 and the second upper connection pad 312 provided on the top surface of the package substrate 300 may be connected to each other. The second conductive pattern SP2 may electrically interconnect at least one second chip pad 123 and the second upper connection pad 312 that need to be connected to each other. The second conductive pattern SP2 may include a conductive material.

As shown in FIG. 2B, the second conductive pattern SP2 may be provided along the top surface and side surfaces of each second semiconductor chip 120. Unlike second conductive patterns SP2 adjacent to the other second semiconductor chips 120, the second conductive pattern SP2 adjacent to the lowermost second semiconductor chip 120B may be provided along side surfaces of the lowermost second semiconductor chip 120B and extend onto the top surface of the first encapsulation member 210. The second conductive pattern SP2 extended onto the top surface of the first encapsulation member 210 may extend to a side surface of the first encapsulation member 210 adjacent to the second upper connection pad 312 and may extend onto the second upper connection pad 312 disposed on the top surface of the package substrate 300 along the side surfaces of the first encapsulation member 210, as shown in FIG. 1.

The second conductive pattern SP2 may extend to the second chip pad 123 of the uppermost second semiconductor chip 120T and the second chip pad 123 of the lowermost second semiconductor chip 120B. The second conductive pattern SP2 may extend from the second chip pad 123 of the lowermost second semiconductor chip 120B through the top surface and the side surfaces of the first encapsulation member 210 to the second upper connection pad 312 of the package substrate 300.

The second encapsulation member 220 may surround the second semiconductor chip stack C2 and the first encapsulation member 210 on the package substrate 300. For example, the second encapsulation member 220 may surround the plurality of second semiconductor chips 120, the second conductive pattern SP2, the second separating insulation layer SIL2, and the first encapsulation member 210 on the top surface of the package substrate 300. As shown in FIG. 2A, the second encapsulation member 220 may cover a portion of the first cover insulation layer CIL1 protruding from the first encapsulation member 210. The second encapsulation member 220 may include, for example, an EMC or a polymer material.

The second encapsulation member 220 may be in contact with a portion of the side surface of the lowermost second semiconductor chip 120 of the second semiconductor chip stack C2. In other words, the first encapsulation member 210 and the second encapsulation member 220 may contact the side surface of the lowermost second semiconductor chip 120B. Also, the second conductive pattern SP2 provided on a surface of the first encapsulation member 210 may be provided between the first encapsulation member 210 and the second encapsulation member 220.

The second encapsulation member 220 may cover the top surface of the uppermost second semiconductor chip 120T. Also, the second encapsulation member 220 may cover the second conductive pattern SP2, and the planar shape of the second encapsulation member 220 may be identical to the planar shape of the package substrate 300. In other words, the side surfaces of the second encapsulation member 220 and the side surfaces of the package substrate 300 may be aligned.

A semiconductor package 1 is electrically connected to the package substrate 300 through the second conductive pattern SP2 on which the second semiconductor chip stack C2 is disposed based on the first encapsulation member 210. In the semiconductor package 1 including a plurality of semiconductor chips stacked in a zigzag shape, electrical connection between the plurality of semiconductor chips and a package substrate may be established through a conductive pattern rather than a conventional bonding wire.

Also, in the semiconductor package 1, a semiconductor chip and an upper connection pad located on a package substrate are connected through a conductive pattern, rather than through a bonding wire between the semiconductor chip and the upper connection pad located on the package substrate. Therefore, the semiconductor package 1 may be formed through patterning of a conductive pattern collectively for demanded connections rather than a bonding wire connection process individually performed for each connection, thereby simplifying the manufacturing process.

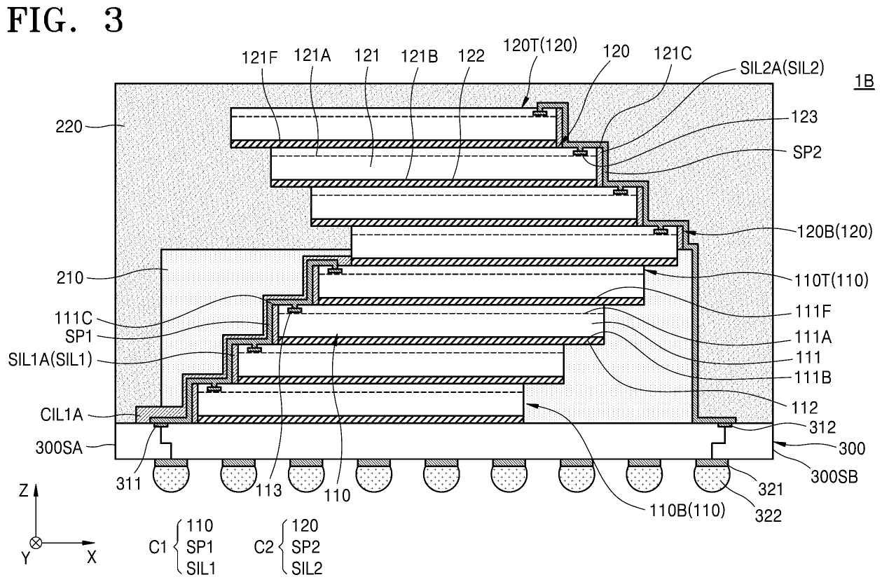

FIG. 3 is a cross-sectional view of an example of a semiconductor package 1B. Descriptions not given below may be substantially identical to descriptions given above.

Referring to FIG. 3, the first semiconductor chip stack C1 may include the plurality of first semiconductor chips 110, the first conductive pattern SP1, and the first separating insulation layer SIL1. The plurality of first semiconductor chips 110 may each include the first semiconductor substrate 111, the first adhesive film 112, and the first chip pad 113.

The first side surface separating insulation layer SIL1A may cover a portion of the side surface of the plurality of first semiconductor chips 110. For example, the first side surface separating insulation layer SIL1A may cover at least a portion of a side surface of the plurality of first semiconductor chips 110 adjacent to the first chip pad 113. Alternatively, at least a portion of a side surface of the plurality of first semiconductor chips 110 facing the first substrate side surface 300SA, which is one of the side surfaces of the package substrate 300, may be covered by the first side surface separating insulation layer SIL1A. The first side surface separating insulation layer SIL1A may be included in the first separating insulation layer SIL1.

A first cover insulation layer CIL1A may cover the first conductive pattern SP1. For example, the first cover insulation layer CIL1A may cover the first conductive pattern SP1 located on the top surface of the package substrate 300 and the first conductive pattern SP1 extending along the side surfaces and the top surface of the plurality of first semiconductor chips 110. The first cover insulation layer CIL1A described with reference to FIG. 3 covers all of the first conductive patterns SP1 not covered by the first cover insulation layer CIL1 in the process of forming the first cover insulation layer CIL1 described above with reference to FIG. 1. Therefore, the first conductive pattern SP1 and the first encapsulation member 210 may be spaced apart from each other by the first cover insulation layer CIL1A. In other words, the first cover insulation layer CIL1A may be provided between the first encapsulation member 210 and the first conductive pattern SP1.

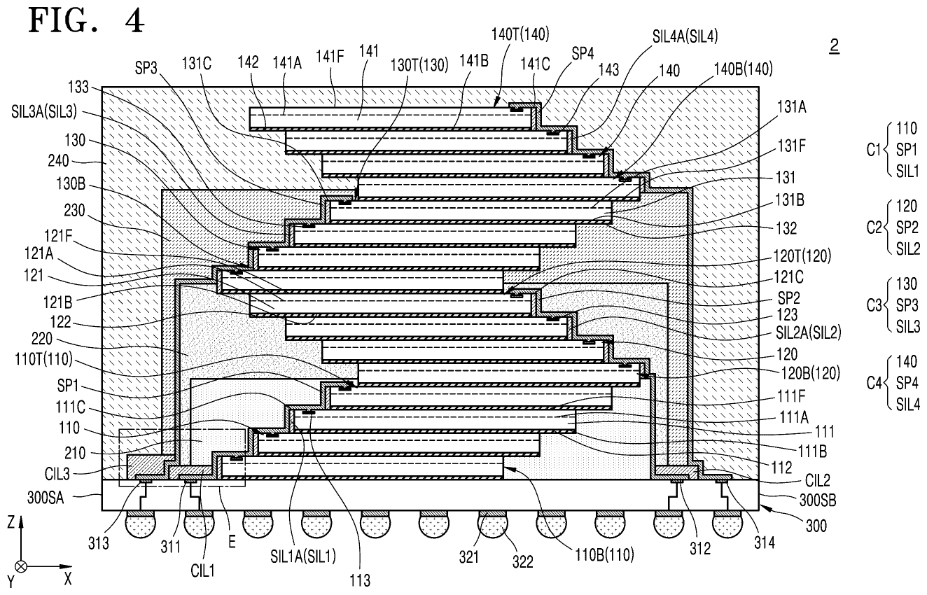

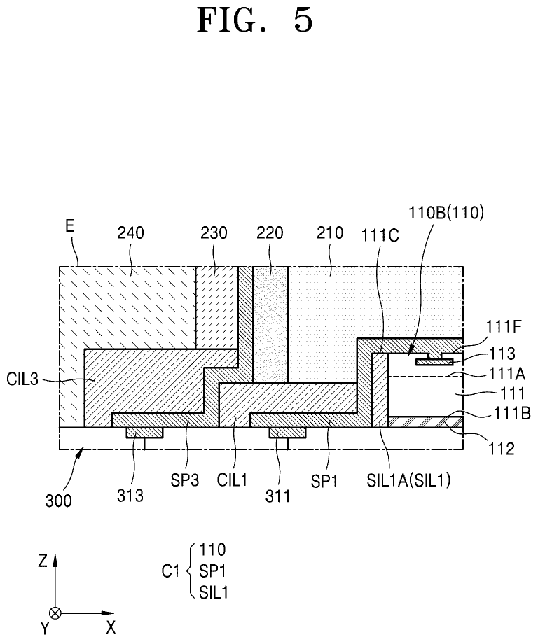

FIG. 4 is a cross-sectional view of an example of a semiconductor package 2. FIG. 5 is an example enlarged cross-sectional view of a portion E of FIG. 4. Descriptions not given below may be substantially identical to descriptions given above.

Referring to FIGS. 4 and 5, the semiconductor package 2 may include the package substrate 300, the first semiconductor chip stack C1, which is provided on the package substrate 300 and includes the plurality of first semiconductor chips 110, the second semiconductor chip stack C2, which is provided on the first semiconductor chip stack C1 and includes the plurality of second semiconductor chips 120, the third semiconductor chip stack C3, which is provided on the second semiconductor chip stack C2 and includes a plurality of third semiconductor chips 130, the fourth semiconductor chip stack C4, which is provided on the third semiconductor chip stack C3 and includes a plurality of fourth semiconductor chips 140, the first encapsulation member 210, the second encapsulation member 220, a third encapsulation member 230, and a fourth encapsulation member 240.

The package substrate 300 may include the first upper connection pad 311, the second upper connection pad 312, the third upper connection pad 313, and the fourth upper connection pad 314 on the top surface of the package substrate 300 and include the external connection pad 321 and the external connection terminal 322, which is provided on the external connection pad 321, on the bottom surface of the package substrate 300. The package substrate 300 may be, for example, a PCB or a redistribution structure.

The first semiconductor chip stack C1 may include the plurality of first semiconductor chips 110, the first conductive pattern SP1, and a first separating insulation layer SIL1. The plurality of first semiconductor chips 110 may each include the first semiconductor substrate 111, the first adhesive film 112, and the first chip pad 113.

The plurality of first semiconductor chips 110 may include two or more first semiconductor chips 110. The plurality of first semiconductor chips 110 may be stacked in a step-like shape. The first chip pad 113 adjacent to the first chip edge 111C may be provided on a portion of the top surface of the first semiconductor chip 110 exposed as the plurality of first semiconductor chips 110 are offset.

The first separating insulation layer SIL1 may include the first side surface separating insulation layer SIL1A. The first side surface separating insulation layer SIL1A may cover a portion of the side surface of the plurality of first semiconductor chips 110. Alternatively, the first side surface separating insulation layer SIL1A may be provided between the first conductive pattern SP1 and the side surfaces of the plurality of first semiconductor chips 110 such that the side surfaces of the first conductive pattern SP1 and the plurality of first semiconductor chips 110 are spaced apart from each other.

The first upper connection pad 311 may be provided on the top surface of the package substrate 300 and laterally spaced from the first semiconductor chip stack C1. The first chip pad 113 provided on each of the plurality of first semiconductor chips 110 may be connected to the first upper connection pad 311 provided on the top surface of the package substrate 300.

The first cover insulation layer CIL1 may cover the first conductive pattern SP1 extending on the package substrate 300 from among first conductive patterns SP1. The first encapsulation member 210 may surround the first semiconductor chip stack C1 on the package substrate 300. The vertical level of the top surface of the first encapsulation member 210 may be higher than the vertical level of the highest portion of the first conductive pattern SP1.

As shown in FIG. 5, the second encapsulation member 220 may be provided on the first cover insulation layer CIL1. For example, since the second encapsulation member 220 surrounds the first encapsulation member 210, the first encapsulation member 210 and the second encapsulation member 220 may be continuously in contact with the top surface of the first cover insulation layer CIL1 with which the first encapsulation member 210 is in contact. A portion of the first cover insulation layer CIL1 may protrude laterally from the second encapsulation member 220. For example, the first cover insulation layer CIL1 may protrude from the second encapsulation member 220 toward the third upper connection pad 313.

A third conductive pattern SP3, which will be described below, may extend along the side surface of the second encapsulation member 220 adjacent to the third upper connection pad 313. As shown in FIG. 5, the third conductive pattern SP3 extending along a side surface of the second encapsulation member 220 adjacent to the third upper connection pad 313 may extend along a portion of the top surface and the side surface of the first cover insulation layer CIL1 and the top surface of the package substrate 300. The third conductive pattern SP3 extending along the top surface of the package substrate 300 may be connected to the third upper connection pad 313.

The first cover insulation layer CIL1 may be in contact with the third conductive pattern SP3 and a third cover insulation layer CIL3 to be described below. In some implementations, the third encapsulation member 230 may be provided on the first cover insulation layer CIL1. For example, when the width of the first cover insulation layer CIL1 in the second direction (Y direction) is greater than the width of the third cover insulation layer CIL3 in the second direction (Y direction), the first cover insulation layer CIL1 may be in contact with the third encapsulation member 230.

The second semiconductor chip stack C2 may include the plurality of second semiconductor chips 120, the second conductive pattern SP2, and a second separating insulation layer SIL2. The plurality of second semiconductor chips 120 may each include a second semiconductor substrate 121, a second adhesive film 122, and a second chip pad 123.

The second semiconductor chip stack C2 may be disposed on the first semiconductor chip stack C1. The plurality of second semiconductor chips 120 may be stacked in a step-like shape. In other words, the second semiconductor chip 120 may be disposed over and offset in a particular direction from the second semiconductor chip 120 located there below. The step-wise stacking direction of the plurality of first semiconductor chips 110 may be different from the step-wise stacking direction of the plurality of second semiconductor chips 120.

The second separating insulation layer SIL2 may cover a portion of the side surface of the plurality of second semiconductor chips 120. Alternatively, the second side surface separating insulation layer SIL2A may be provided between the second conductive pattern SP2 and the side surfaces of the plurality of second semiconductor chips 120 such that the side surfaces of the second conductive pattern SP2 and the plurality of second semiconductor chips 120 are spaced apart from each other. The vertical height of the second side surface separating insulation layer SIL2A disposed on the side surface of the lowermost second semiconductor chip 120B may be less than the vertical height of the second side surface separating insulation layer SIL2A arranged on the side surface of another second semiconductor chip 120.

The second upper connection pad 312 may be provided on the top surface of the package substrate 300 and laterally spaced from a first encapsulation member 310. The second upper connection pad 312 may be provided in a direction different from the direction in which the first upper connection pad 311 is located with respect to the first semiconductor chip stack C1.

The second conductive pattern SP2 may be connected to the second chip pad 123 provided on each of the plurality of second semiconductor chips 120 and the second upper connection pad 312 provided on the top surface of the package substrate 300. The second conductive pattern SP2 may be provided along the top surface and side surfaces of each second semiconductor chip 120. The second conductive pattern SP2 may be connected to the second chip pad 123 of the uppermost second semiconductor chip 120T and the second chip pad 123 of the lowermost second semiconductor chip 120B.

Unlike second conductive patterns SP2 adjacent to the other second semiconductor chips 120, the second conductive pattern SP2 adjacent to the lowermost second semiconductor chip 120B may be provided along side surfaces of the lowermost second semiconductor chip 120B and extend onto the top surface of the first encapsulation member 210. The second conductive pattern SP2 extended onto the top surface of the first encapsulation member 210 may extend to a side surface of the first encapsulation member 210 adjacent to the second upper connection pad 312 and may extend onto the second upper connection pad 312 disposed on the top surface of the package substrate 300 along the side surfaces of the first encapsulation member 210, as shown in FIG. 1.

The second conductive pattern SP2 may extend along the top surface of the second semiconductor chip 120, the second separating insulation layer SIL2, the first encapsulation member 210, and the package substrate 300. In other words, the second conductive pattern SP2 may be provided between the second semiconductor chip 120, the second separating insulation layer SIL2, the first encapsulation member 210, and the top surface of the package substrate 300 and the second encapsulation member 220 and a second cover insulation layer CIL2.

The second cover insulation layer CIL2 may cover the second conductive pattern SP2 extending on the package substrate 300 from among second conductive patterns SP2. The second cover insulation layer CIL2 may cover the second conductive pattern SP2 and may be provided on the top surface of the package substrate 300. The second cover insulation layer CIL2 may be provided on a side surface of the first encapsulation member 210 adjacent to the second upper connection pad 312.

A portion of the second conductive pattern SP2 provided on the side surface of the first encapsulation member 210 adjacent to the second upper connection pad 312 may be provided on the second cover insulation layer CIL2. The second cover insulation layer CIL2 may be provided on a side surface of the first encapsulation member 210 adjacent to the second upper connection pad 312 of the first encapsulation member 210, which is not provided with the second conductive pattern SP2.

The second encapsulation member 220 may surround the second semiconductor chip stack C2 on the package substrate 300. The second encapsulation member 220 may cover at least a portion of the second cover insulation layer CIL2. In other words, a portion of the second cover insulation layer CIL2 may protrude from the boundary of the second encapsulation member 220. As described below, a portion of the second cover insulation layer CIL2 may protrude from the boundary of the third encapsulation member 230. Therefore, for example, since the third encapsulation member 230 surrounds the second encapsulation member 220, the second encapsulation member 220 and the third encapsulation member 230 may be continuously provided on the top surface of the second cover insulation layer CIL2.

The second encapsulation member 220 may surround the plurality of second semiconductor chips 120 included in the second semiconductor chip stack C2. The third encapsulation member 230 may be provided on side surfaces of a lowermost third semiconductor chip 130B closest to the package substrate 300 from among the plurality of third semiconductor chips 130. Alternatively, the top surface of the second encapsulation member 220 may be provided on a side surface of the lowermost third semiconductor chip 130B.

The vertical level of the top surface of the second encapsulation member 220 may be higher than the vertical level of the highest portion of the second conductive pattern SP2. In other words, the second encapsulation member 220 may cover the second conductive pattern SP2 connected to the uppermost second semiconductor chip 120T, which is the highest portion of the second conductive pattern SP2.

A third semiconductor chip stack C3 may include the plurality of third semiconductor chips 130, the third conductive pattern SP3, and a third separating insulation layer SIL3. The plurality of third semiconductor chips 130 may each include a third semiconductor substrate 131, a third adhesive film 132, and a third chip pad 133.

The plurality of third semiconductor chips 130 may include two or more third semiconductor chips 130. The plurality of third semiconductor chips 130 may be stacked in a step-like shape. The third chip pad 133 adjacent to the third chip edge 131C may be provided on a portion of a third substrate top surface 131F exposed due to the offset of the plurality of third semiconductor chips 130. The plurality of third semiconductor chips 130 may include the lowermost third semiconductor chip 130B located closest to the package substrate 300 from among the plurality of third semiconductor chips 130 and an uppermost third semiconductor chip 130T located farthest from the package substrate 300 from among the plurality of third semiconductor chips 130.

The step-wise stacking direction of the plurality of third semiconductor chips 130 and the step-wise stacking direction of the plurality of first semiconductor chips 110 may be identical to each other. For example, since the step-wise stacking direction of the plurality of first semiconductor chips 110 is the positive first direction and the step-wise stacking direction of the plurality of third semiconductor chips 130 is also the positive first direction, the step-wise stacking direction of the plurality of first semiconductor chips 110 and the step-wise stacking direction of the plurality of third semiconductor chips 130 are identical to each other. In other words, the step-wise stacking direction of the plurality of first semiconductor chips 110 and the step-wise stacking direction of the plurality of third semiconductor chips 130 may be identical to each other, and the step-wise stacking direction of the plurality of first semiconductor chips 110 and the step-wise stacking direction of the plurality of third semiconductor chips 130 may be different from the step-wise stacking direction of the plurality of second semiconductor chips 120.

The third chip pad 133 adjacent to the third chip edge 131C may be provided on a portion of the third substrate top surface 131F exposed due to the offset of the plurality of third semiconductor chips 130. In other words, the third chip pad 133 may be positioned on the top surface of each exposed third substrate top surface 131F of the plurality of third semiconductor chips 130 stacked in a step-like shape.

The third adhesive film 132 may be attached to the bottom surface of each of the plurality of third semiconductor chips 130, and thus the plurality of third semiconductor chips 130 may be attached to structures there below.

The third separating insulation layer SIL3 may include a third side surface separating insulation layer SIL3A. The third side surface separating insulation layer SIL3A may cover a portion of the side surface of the plurality of third semiconductor chips 130. Alternatively, the third side surface separating insulation layer SIL3A may be provided between the third conductive pattern SP3 and the side surfaces of the plurality of third semiconductor chips 130 such that the side surfaces of the third conductive pattern SP3 and the plurality of third semiconductor chips 130 are spaced apart from each other. The detailed description of the third separating insulation layer SIL3 is substantially similar to that of the second separating insulation layer SIL2 given above.

The vertical height of the third side surface separating insulation layer SIL3A disposed on the side surface of the lowermost third semiconductor chip 130B may be less than the vertical height of the third side surface separating insulation layer SIL3A arranged on the side surface of another third semiconductor chip 130. The top surface of the second encapsulation member 220 may contact a side surface of the lowermost third semiconductor chip 130B. In other words, a portion of the side surface of the lowermost third semiconductor chip 130B may contact the second encapsulation member 220. The third side surface separating insulation layer SIL3A may be provided on the remaining side surface of the lowermost third semiconductor chip 130B, which is not in contact with the second encapsulation member 220. The third separating insulation layer SIL3 may include an insulation material. Detailed descriptions of the constituent materials of the third separating insulation layer SIL3 may be substantially identical to those of the first separating insulation layer SIL1.

The third upper connection pad 313 may be provided on the top surface of the package substrate 300 and laterally spaced from the third semiconductor chip stack C3. The third upper connection pad 313 may be positioned closer to the outer edge of the package substrate 300 than the first upper connection pad 311 is. The first upper connection pad 311 and the third upper connection pad 313 may be provided in the same direction with respect to the first semiconductor chip stack C1, and the second upper connection pad 312 may be provided in a direction different from that of the first upper connection pad 311 and the third upper connection pad 313. For example, the first upper connection pad 311 and the third upper connection pad 313 may be arranged on the package substrate 300 in the negative first direction with respect to the first semiconductor chip stack C1, and the second upper connection pad 312 may be disposed on the package substrate 300 in the positive first direction with respect to the first semiconductor chip stack C1.

Through the third conductive pattern SP3, the third chip pad 133 provided on each of the plurality of third semiconductor chips 130 and the third upper connection pad 313 provided on the top surface of the package substrate 300 may be connected to each other. The third conductive pattern SP3 may electrically interconnect at least one third chip pad 133 and the third upper connection pad 313 that need to be connected to each other. The third conductive pattern SP3 may include a conductive material.

A portion of the third conductive pattern SP3 may be provided on a surface of the second encapsulation member 220. The third conductive pattern SP3 may be provided along the top surface and side surfaces of each third semiconductor chip 130. Unlike third conductive patterns SP3 adjacent to the other third semiconductor chips 130, the third conductive pattern SP3 adjacent to the lowermost third semiconductor chip 130B may be provided along side surfaces of the lowermost third semiconductor chip 130B and extend onto the top surface of the second encapsulation member 220. The third conductive pattern SP3 extended to the top surface of the second encapsulation member 220 may extend to the side surface of the second encapsulation member 220 adjacent to the third upper connection pad 313 and be connected to the third upper connection pad 313 arranged on the top surface of the package substrate 300 along the side surface of the second encapsulation member 220.

The third conductive pattern SP3 may extend to the top surface of the second encapsulation member 220, the side surface of the second encapsulation member 220 adjacent to the third upper connection pad 313, and the top surface of the first cover insulation layer CIL1. The third conductive pattern SP3 may extend along a portion of the top surface and a side surface of the first cover insulation layer CIL1 and may extend along the top surface of the package substrate 300. The third conductive pattern SP3 extending along the top surface of the package substrate 300 may be connected to the third upper connection pad 313.

The third conductive pattern SP3 may extend along the top surface of the third semiconductor chip 130, the third separating insulation layer SIL3, the second encapsulation member 220, the first cover insulation layer CIL1, and the package substrate 300. In other words, the third conductive pattern SP3 may be provided between the third semiconductor chip 130, the third separating insulation layer SIL3, the second encapsulation member 220, the first cover insulation layer CIL1, and the top surface of the package substrate 300 and the third encapsulation member 230 and the third cover insulation layer CIL3.

The third encapsulation member 230 may surround the third semiconductor chip stack C3 on the package substrate 300. For example, the third encapsulation member 230 may surround the plurality of third semiconductor chips 130, the third conductive pattern SP3, the third separating insulation layer SIL3, and the second encapsulation member 220 on the top surface of the package substrate 300. As shown in FIG. 2A, the third encapsulation member 230 may cover a portion of the third cover insulation layer CIL3. In other words, a portion of the third cover insulation layer CIL3 may protrude from the boundary of the third encapsulation member 230.

The fourth encapsulation member 240 may be provided on the third cover insulation layer CIL3. For example, since the fourth encapsulation member 240 surrounds the third encapsulation member 230, the third encapsulation member 230 and the fourth encapsulation member 240 may be continuously provided on the top surface of the third cover insulation layer CIL3. The third cover insulation layer CIL3 may not protrude laterally from the fourth encapsulation member 240. Since the third conductive pattern SP3 is provided on a portion of the side surface of the second encapsulation member 220 adjacent to the third upper connection pad 313, the second encapsulation member 220 and the third cover insulation layer CIL3 may partially contact each other.

The vertical level of the top surface of the third encapsulation member 230 may be higher than the vertical level of the highest portion of the third conductive pattern SP3. In other words, the third encapsulation member 230 may cover the third conductive pattern SP3 connected to the uppermost third semiconductor chip 130T, which is the highest portion of the third conductive pattern SP3.

A portion of a fourth conductive pattern SP4, which will be described below, may be provided on a surface of the third encapsulation member 230. For example, the fourth conductive pattern SP4 may extend along a side surface of the third encapsulation member 230 adjacent to the fourth upper connection pad 314, and the fourth conductive pattern SP4 may be connected to the fourth upper connection pad 314 provided on the package substrate 300.

The fourth semiconductor chip stack C4 may include the plurality of fourth semiconductor chips 140, the fourth conductive pattern SP4, and a fourth separating insulation layer SIL4. The fourth semiconductor chips 140 may each include a fourth semiconductor substrate 141, a fourth adhesive film 142, and a fourth chip pad 143. The fourth semiconductor chip stack C4 may be referred to as the uppermost semiconductor chip stack.

The plurality of fourth semiconductor chips 140 may include two or more fourth semiconductor chips 140. The plurality of fourth semiconductor chips 140 may be stacked in a step-like shape. The fourth chip pad 143 adjacent to the fourth chip edge 141C may be provided on a portion of a fourth substrate top surface 141F exposed due to the offset of the plurality of fourth semiconductor chips 140. The plurality of fourth semiconductor chips 140 may include a lowermost fourth semiconductor chip 140B located closest to the package substrate 300 from among the plurality of fourth semiconductor chips 140 and an uppermost fourth semiconductor chip 140T located farthest from the package substrate 300 from among the plurality of fourth semiconductor chips 140.

The step-wise stacking direction of the plurality of fourth semiconductor chips 140 and the step-wise stacking direction of the plurality of second semiconductor chips 120 may be identical to each other. For example, since the step-wise stacking direction of the plurality of second semiconductor chips 120 is the negative first direction and the step-wise stacking direction of the plurality of fourth semiconductor chips 140 is also the negative first direction, the step-wise stacking direction of the plurality of second semiconductor chips 720 and the step-wise stacking direction of the plurality of fourth semiconductor chips 140 are identical to each other. In other words, the step-wise stacking direction of the plurality of second semiconductor chips 120 and the step-wise stacking direction of the plurality of fourth semiconductor chips 140 may be identical to each other, and the step-wise stacking direction of the plurality of first semiconductor chips 110 and the step-wise stacking direction of the plurality of third semiconductor chips 130 may be different from the step-wise stacking direction of the plurality of second semiconductor chips 120 and the step-wise stacking direction of the plurality of fourth semiconductor chips 140.

The fourth chip pad 143 adjacent to the fourth chip edge 141C may be provided on a portion of a fourth substrate top surface 141F exposed due to the offset of the plurality of fourth semiconductor chips 140. In other words, the fourth chip pad 143 may be positioned on the top surface of each exposed fourth substrate top surface 141F of the plurality of fourth semiconductor chips 140 stacked in a step-like shape.

The fourth adhesive film 142 may be attached to the bottom surface of each of the plurality of fourth semiconductor chips 140, and thus the plurality of fourth semiconductor chips 140 may be attached to structures there below.

The fourth separating insulation layer SIL4 may include a fourth side surface separating insulation layer SIL4A. The fourth side surface separating insulation layer SIL4A may cover a portion of the side surface of the plurality of fourth semiconductor chips 140. Alternatively, the fourth side surface separating insulation layer SIL4A may be provided between the fourth conductive pattern SP4 and the side surfaces of the plurality of fourth semiconductor chips 140, such that the side surfaces of the fourth conductive pattern SP4 and the plurality of fourth semiconductor chips 140 are spaced apart from each other. The detailed description of the fourth separating insulation layer SIL4 is substantially identical to that of the first separating insulation layer SIL1 given above.

The vertical height of the fourth side surface separating insulation layer SIL4A disposed on the side surface of the lowermost fourth semiconductor chip 140B may be less than the vertical height of the fourth side surface separating insulation layer SIL4A arranged on the side surface of another fourth semiconductor chip 140. The top surface of the third encapsulation member 230 may contact a side surface of the lowermost fourth semiconductor chip 140B. In other words, a portion of the side surface of the lowermost fourth semiconductor chip 140B may contact the second encapsulation member 220. The fourth side surface separating insulation layer SIL4A may be provided on the remaining side surface of the lowermost fourth semiconductor chip 140B, which is not in contact with the third encapsulation member 230. The fourth separating insulation layer SIL4 may include an insulation material. Detailed descriptions of the constituent materials of the fourth separating insulation layer SIL4 may be substantially identical to those of the first separating insulation layer SIL1.

The fourth upper connection pad 314 may be provided on the top surface of the package substrate 300 and laterally spaced from the fourth semiconductor chip stack C4. The fourth upper connection pad 314 may be positioned closer to the outer edge of the package substrate 300 than the second upper connection pad 312 is. The second upper connection pad 312 and the fourth upper connection pad 314 may be provided in the same direction with respect to the first semiconductor chip stack C1. The first upper connection pad 311 and the third upper connection pad 313 may be provided in a direction different from that of the second upper connection pad 312 and the fourth upper connection pad 314. For example, the first upper connection pad 311 and the third upper connection pad 313 may be arranged on the package substrate 300 in the negative first direction with respect to the first semiconductor chip stack C1, and the second upper connection pad 312 and the fourth upper connection pad 314 may be arranged on the package substrate 300 in the positive first direction with respect to the first semiconductor chip stack C1.

Through the fourth conductive pattern SP4, the fourth chip pad 143 provided on each of the plurality of fourth semiconductor chips 140 and the fourth upper connection pad 314 provided on the top surface of the package substrate 300 may be connected to each other. The fourth conductive pattern SP4 may electrically interconnect at least one fourth chip pad 143 and the fourth upper connection pad 314 that need to be connected to each other. The fourth conductive pattern SP4 may include a conductive material.

The fourth conductive pattern SP4 may be provided along the top surface and side surfaces of each fourth semiconductor chip 140. Unlike the fourth conductive pattern SP4 adjacent to another fourth semiconductor chip 140, the fourth conductive pattern SP4 adjacent to the lowermost fourth semiconductor chip 140B may extend from side surfaces of the lowermost fourth semiconductor chip 140B to the top surface of the third encapsulation member 230.

The fourth conductive pattern SP4 may extend to the top surface of the third encapsulation member 230, a side surface of the third encapsulation member 230 adjacent to the fourth upper connection pad 314 from among side surfaces of the third encapsulation member 230, and the top surface of the second cover insulation layer CIL2. The fourth conductive pattern SP4 may extend along a portion of the top surface and a side surface of the second cover insulation layer CIL2 and may extend along the top surface of the package substrate 300. The fourth conductive pattern SP4 extending along the top surface of the package substrate 300 may be connected to the fourth upper connection pad 314.

The fourth conductive pattern SP4 may extend along the top surface of the fourth semiconductor chip 140, the fourth separating insulation layer SIL4, the third encapsulation member 230, the second cover insulation layer CIL2, and the package substrate 300. In other words, the fourth conductive pattern SP4 may be provided between the fourth semiconductor chip 140, the fourth separating insulation layer SIL4, the third encapsulation member 230, the second cover insulation layer CIL2, and the top surface of the package substrate 300 and the fourth encapsulation member 240.

The fourth encapsulation member 240 may surround the fourth semiconductor chip stack C4 on the package substrate 300. For example, the fourth encapsulation member 240 may surround the plurality of fourth semiconductor chips 140, the fourth conductive pattern SP4, the fourth separating insulation layer SIL4, and the third encapsulation member 230 on the top surface of the package substrate 300. The vertical level of the top surface of the fourth encapsulation member 240 may be higher than the vertical level of the highest portion of the fourth conductive pattern SP4. In other words, the fourth encapsulation member 240 may cover the fourth conductive pattern SP4 connected to the uppermost fourth semiconductor chip 140T, which is the highest portion of the fourth conductive pattern SP4. The fourth encapsulation member 20) may cover the top surface of the uppermost fourth semiconductor chip 140T. Based on the top surface of the package substrate 300, one vertical level of the fourth encapsulation member may be higher than the vertical level of entire first to fourth semiconductor chip stacks C1, C2, C3, and C4.

The fourth encapsulation member 240 may be provided on the second cover insulation layer CIL2. The fourth conductive pattern SP4 may be disposed on the top surface and side surfaces of the second cover insulation layer CIL2, and the fourth encapsulation member 240 may be provided on the top surface and the side surface of the second cover insulation layer CIL2 where the fourth conductive pattern SP4 is not disposed.

The planar shape of the fourth encapsulation member 240 may be identical to the planar shape of the package substrate 300. In other words, the side surfaces of the fourth encapsulation member 240 and the side surfaces of the package substrate 300 may be aligned.

As described above, the first encapsulation member 210 may surround the first semiconductor chip stack C1, the second encapsulation member 220 may surround the second semiconductor chip stack C2 while surrounding the first encapsulation member 210, the third encapsulation member 230 may surround the third semiconductor chip stack C3 while surrounding the second encapsulation member 220, and the fourth encapsulation member 240 may surround the fourth semiconductor chip stack C4 while surrounding the third encapsulation member 230. In other words, a plurality of encapsulation members may sequentially surround corresponding semiconductor chip stacks from among a plurality of semiconductor chip stacks and encapsulation members located inside a package substrate.

The first encapsulation member 210, the second encapsulation member 220, and the third conductive pattern SP3 may be provided on the first cover insulation layer CIL1. The second encapsulation member 220, the third encapsulation member 230, and the fourth conductive pattern SP4 may be provided on the second cover insulation layer CIL2. The third encapsulation member 230 and the fourth encapsulation member 240 may be provided on the third cover insulation layer CIL3.

The first encapsulation member 210 may be provided on a first portion of the first cover insulation layer CIL1, the second encapsulation member 220 may be provided on a second portion of the first cover insulation layer CIL1, and the third conductive pattern SP3 may be provided on a third portion of the first cover insulation layer CIL1. The second encapsulation member 220 may be provided on a first portion of the second cover insulation layer CIL2, the third encapsulation member 230 may be provided on a second portion of the second cover insulation layer CIL2, and the fourth conductive pattern SP4 may be provided on a third portion of the second cover insulation layer CIL2. The third encapsulation member 230 may be provided on a first portion of the third cover insulation layer CIL3, and the fourth encapsulation member 240 may be provided on a second portion of the third cover insulation layer CIL3.

In the semiconductor package 2, the first encapsulation member 210 may support the first semiconductor chip stack C1, the second encapsulation member 220 may support the second semiconductor chip stack C2, and the third encapsulation member 230 may support the third semiconductor chip stack C3. In other words, since first to third encapsulation members 210, 220, and 230 support a plurality of semiconductor chips included in the semiconductor package 2, the structural reliability of the semiconductor package 2 may be improved.

In some implementations, the semiconductor package 2 may be electrically connected to the package substrate 300 through second to fourth conductive patterns SP2, SP3, and SP4 in which second to fourth semiconductor chip stacks C2, C3, and C4 are respectively arranged based on first to third encapsulation members 210, 220, and 230. Therefore, in the semiconductor package 2 including a plurality of semiconductor chips stacked in a zigzag shape, electrical connection between the plurality of semiconductor chips and a package substrate may be established through a conductive pattern rather than a conventional bonding wire.

Also, in the semiconductor package 2, a semiconductor chip and an upper connection pad located on a package substrate are connected through a conductive pattern, rather than through a bonding wire between the semiconductor chip and the upper connection pad located on the package substrate. Therefore, the semiconductor package 2 may be manufactured through a simplified process, and the structural reliability of the semiconductor package 2 may be secured.

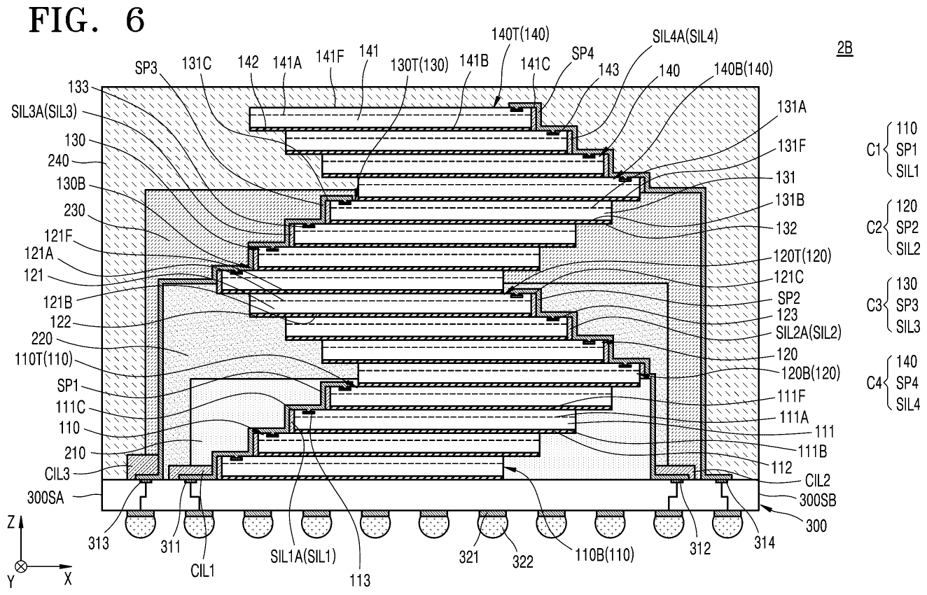

FIG. 6 is a cross-sectional view of an example of a semiconductor package 2B. Descriptions not given below with reference to FIG. 6 may be substantially identical to descriptions given above.

Referring to FIG. 6, the semiconductor package 2B may include the package substrate 300, the first semiconductor chip stack C1, which is provided on the package substrate 300 and includes the plurality of first semiconductor chips 110, the second semiconductor chip stack C2, which is provided on the first semiconductor chip stack C1 and includes the plurality of second semiconductor chips 120, the third semiconductor chip stack C3, which is provided on the second semiconductor chip stack C2 and includes a plurality of third semiconductor chips 130, the fourth semiconductor chip stack C4, which is provided on the third semiconductor chip stack C3 and includes a plurality of fourth semiconductor chips 140, the first encapsulation member 210, the second encapsulation member 220, the third encapsulation member 230, and the fourth encapsulation member 240.

A first cover insulation layer CIL1 may cover the first conductive pattern SP1 extending on the package substrate 300 from among first conductive patterns SP1. The second encapsulation member 220 may be provided on the first cover insulation layer CIL1. The first encapsulation member (210) and the second encapsulation member 220 may be continuously provided on the top surface of the first cover insulation layer CIL1. The first cover insulation layer CIL1 may not protrude laterally from the second encapsulation member 220. A portion of the first cover insulation layer CIL1 protruding from the side surfaces of the first encapsulation member 210 may be covered by the second encapsulation member 220. Accordingly, unlike the semiconductor package 2 of FIG. 4, in the semiconductor package 2B of FIG. 6, the third conductive pattern SP3 may not contact the first cover insulation layer CIL1.

The second cover insulation layer CIL2 may cover the second conductive pattern SP2 extending on the package substrate 300 from among second conductive patterns SP2. The second cover insulation layer CIL2 may cover the second conductive pattern SP2 and may be provided on the top surface of the package substrate 300. The second cover insulation layer CIL2 may be in contact with the second side surface separating insulation layer SIL2A. The second cover insulation layer CIL2 may be connected to a side surface of the first encapsulation member 210 adjacent to the second upper connection pad 312.

Since the third encapsulation member 230 surrounds the second encapsulation member 220, the second encapsulation member 220 and the third encapsulation member 230 may be continuously provided on the top surface of the second cover insulation layer CIL2. The second encapsulation member 220 may cover at least a portion of the second cover insulation layer CIL2. In other words, a portion of the second cover insulation layer CIL2 may protrude laterally from the second encapsulation member 220. For example, the second cover insulation layer CIL2 may protrude from the second encapsulation member 220 toward the fourth upper connection pad 314. However, the second cover insulation layer CIL2 may not protrude from the third encapsulation member 230.

The third encapsulation member 230 may cover a portion of the third cover insulation layer CIL3. In other words, a portion of the third cover insulation layer CIL3 may protrude from side surfaces of the third encapsulation member 230. The fourth encapsulation member 240 may be provided on the third cover insulation layer CIL3. Since the fourth encapsulation member 240 surrounds the third encapsulation member 230, the third encapsulation member 230 and the fourth encapsulation member 240 may continuously contact the top surface of the third cover insulation layer CIL3.

The third cover insulation layer CIL3 may not protrude laterally from the fourth encapsulation member 240. Although the third conductive pattern SP3 is provided on a portion of a side surface of the second encapsulation member 220 adjacent to the third upper connection pad 313, the third conductive pattern SP3 is not provided on the entire side surfaces adjacent of the second encapsulation member 220 to the third upper connection pad 313, and thus the second encapsulation member 220 and the third cover insulation layer CIL3 may partially contact each other.

The first encapsulation member 210 and the second encapsulation member 220 may be provided on the first cover insulation layer CIL1. The second encapsulation member 220 and the third encapsulation member 230 may be provided on the second cover insulation layer CIL2. The third encapsulation member 230 and the fourth encapsulation member 240 may be provided on the third cover insulation layer CIL3.

The first encapsulation member 210 may be provided on a first portion of the first cover insulation layer CIL1, and the second encapsulation member 220 may be provided on a second portion of the first cover insulation layer CIL1. The second encapsulation member 220 may be provided on a first portion of the second cover insulation layer CIL2, and the third encapsulation member 230 may be provided on a second portion of the second cover insulation layer CIL2. The third encapsulation member 230 may be provided on a first portion of the third cover insulation layer CIL3, and the fourth encapsulation member 240 may be provided on a second portion of the third cover insulation layer CIL3.

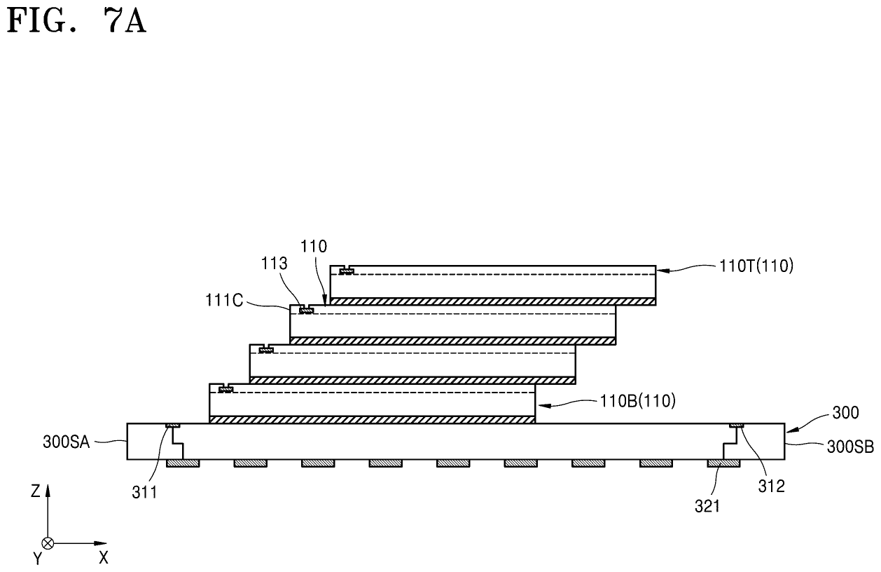

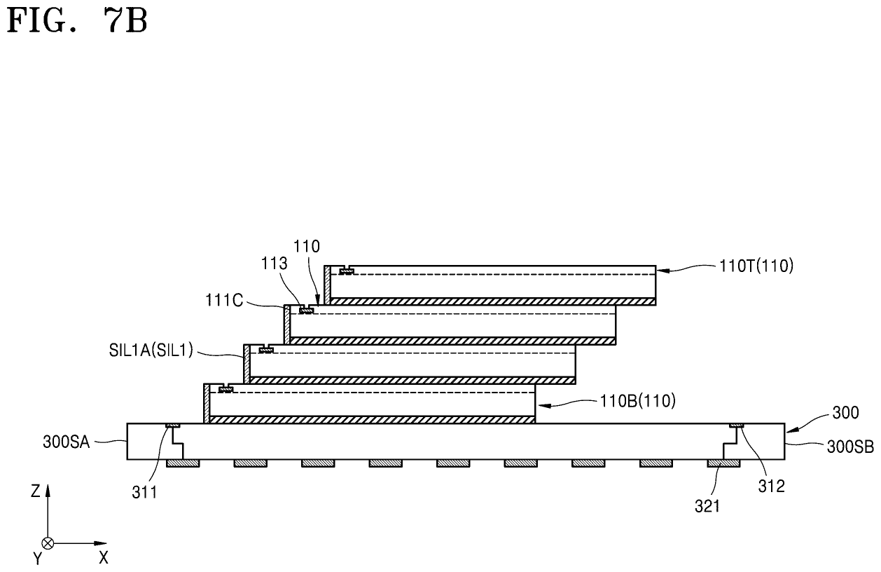

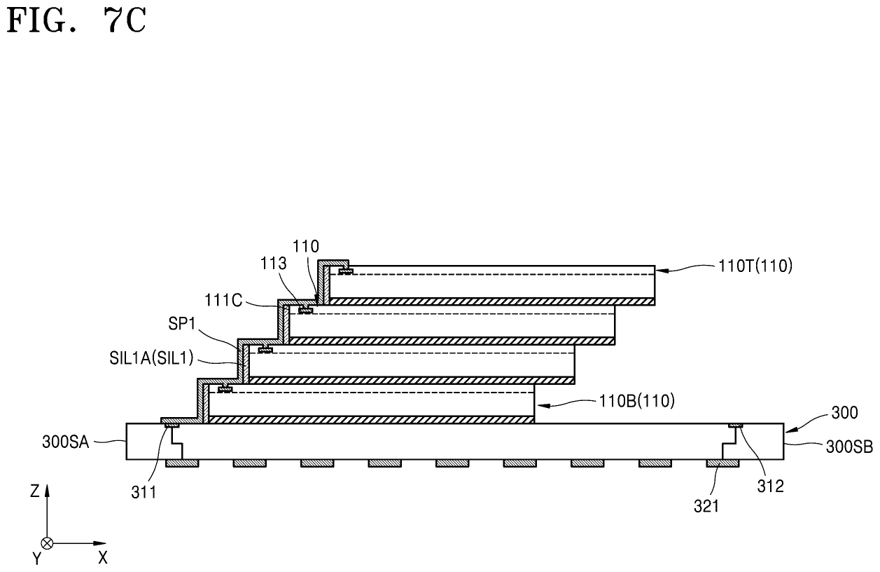

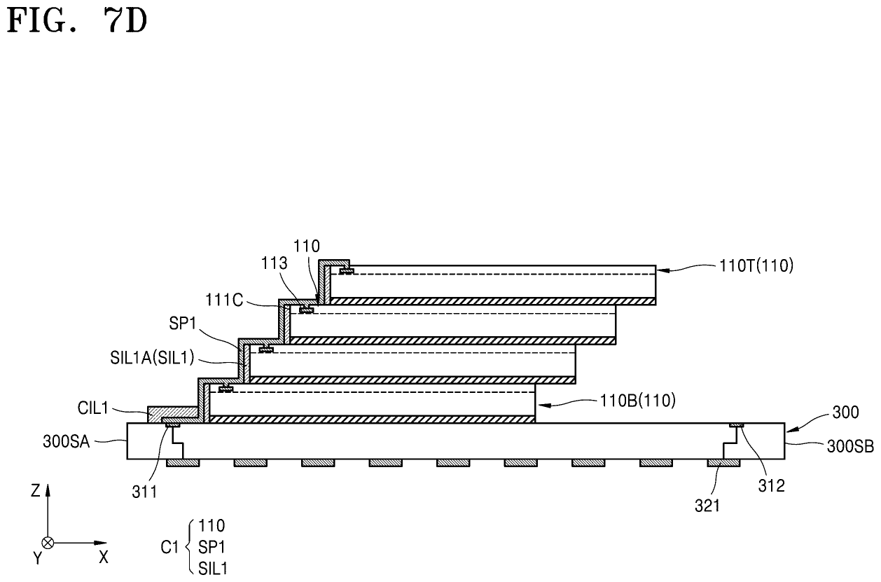

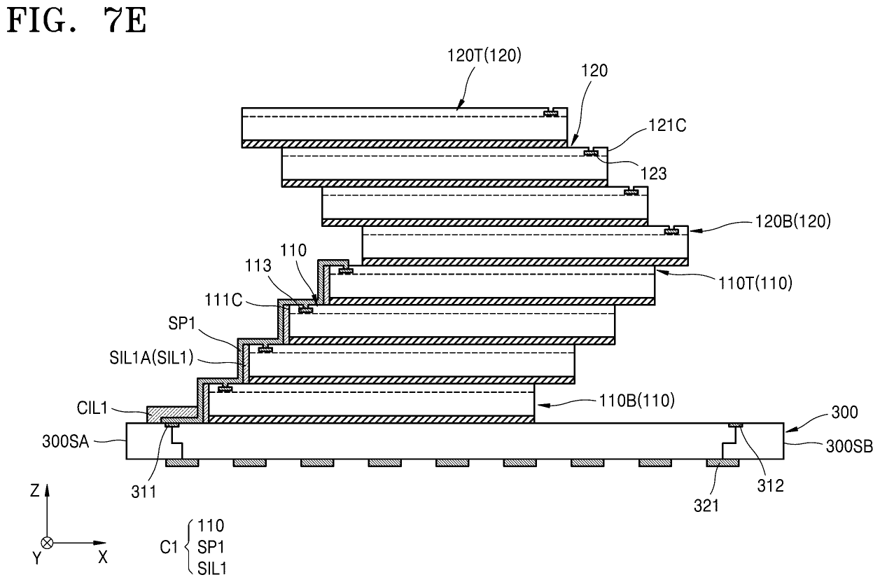

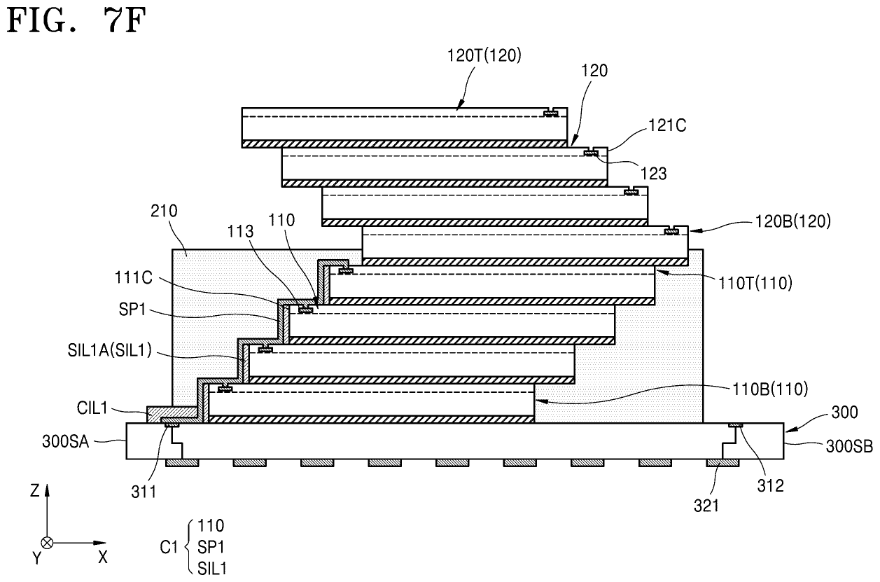

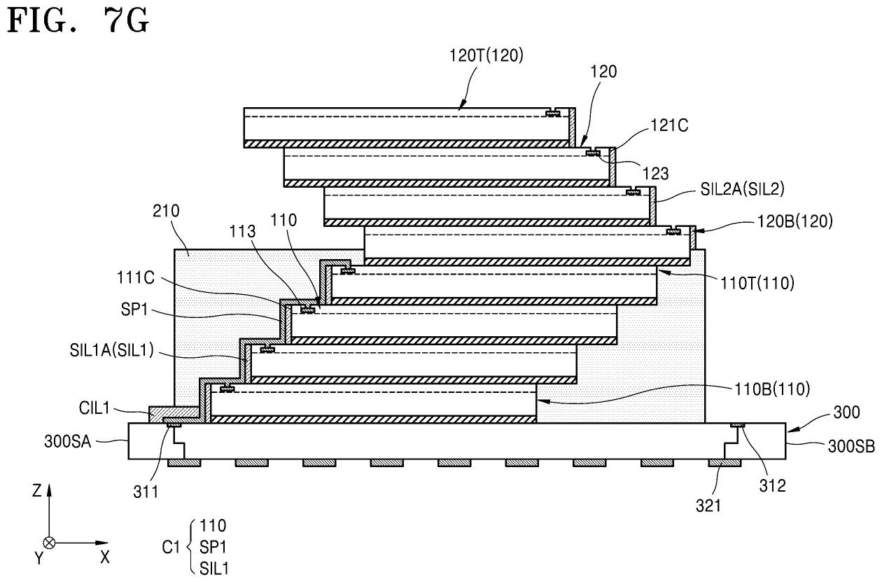

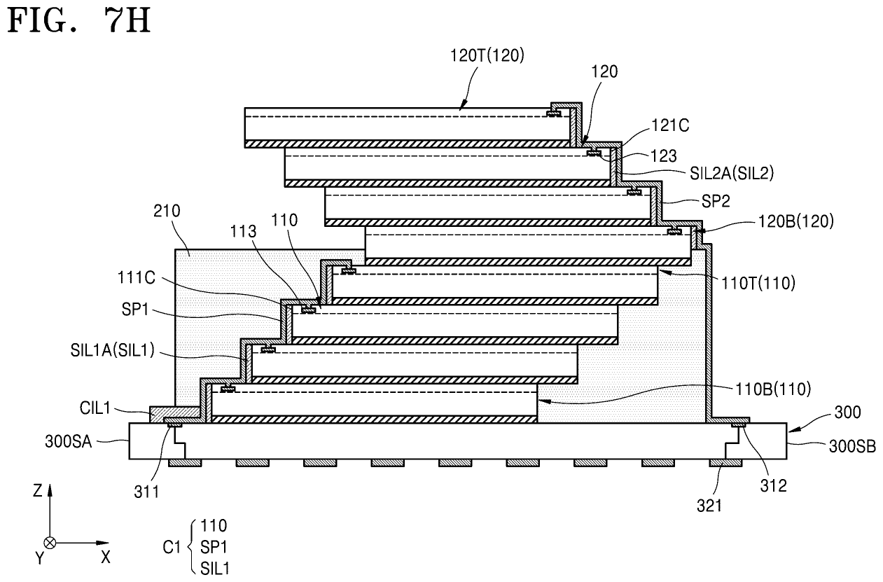

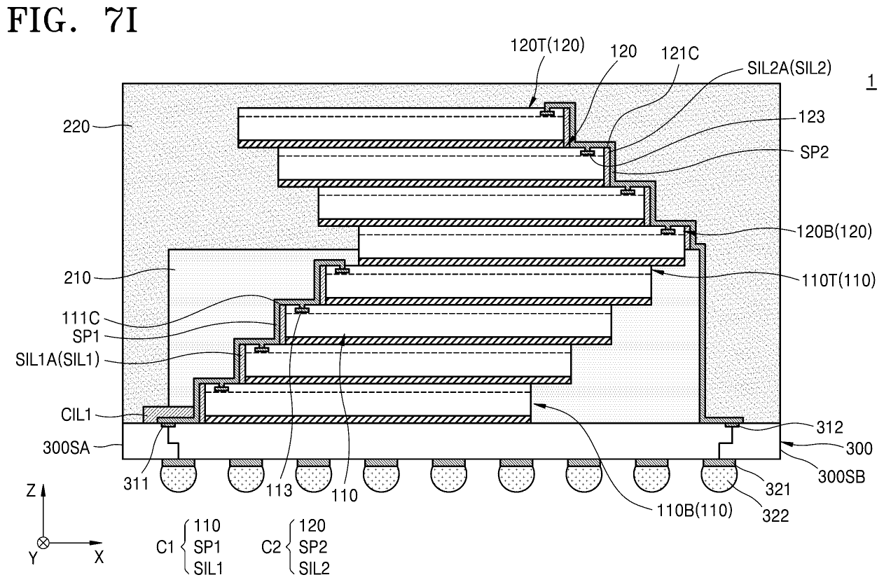

FIGS. 7A, 7B, 7C, 7D, 7E, 7F, 7G, 7H, and 7I are cross-sectional views sequentially showing an example of a process for manufacturing the semiconductor package 1. Descriptions not given below with reference to FIGS. 7A to 7I may be substantially identical to descriptions given above.

Referring to FIG. 7a, the plurality of first semiconductor chips 110 may be stacked and arranged in a step-like shape on the package substrate 300. From among the plurality of first semiconductor chips 110, the lowermost first semiconductor chip 110B may be positioned closer to the first upper connection pad 311 than to the second upper connection pad 312 provided on the top surface of the package substrate 300. Also, the plurality of first semiconductor chips 110 may be stacked in a step-like shape as a first semiconductor chip 110 is offset in a direction away from the first upper connection pad 311 as compared to another first semiconductor chips 110 below the corresponding first semiconductor chip 110.

Referring to FIG. 7B, the first side surface separating insulation layer SIL1A may be formed on the side surfaces of the plurality of first semiconductor chips 110. For example, the first side surface separating insulation layer SIL1A may be formed on the side surfaces of each of the plurality of first semiconductor chips 110 close to the first upper connection pad 311 disposed on the package substrate 300. The first side surface separating insulation layer SIL1A may include at least one of, for example, parylene, Teflon, and an epoxy mold compound. The first side surface separating insulation layer SIL1A may be formed by using various methods such as CVD, spin coating, spray coating, and dipping.

Referring to FIG. 7C, the first conductive pattern SP1 may be formed along the step-like shape of the plurality of first semiconductor chips 110. The first conductive pattern SP1 may extend along the top surface of each of the plurality of first semiconductor chips 110, the first side surface separating insulation layer SIL1A, and the top surface of the package substrate 300. The first conductive pattern SP1 may be connected to the first chip pad 113 disposed on the top surface of each of the plurality of first semiconductor chips 110 and the first upper connection pad 311 of the package substrate 300. For example, a first seed layer for the first conductive pattern SP1 may be first formed at a location where the first conductive pattern SP1 is to be formed, and then the first conductive pattern SP1 may be formed on the first seed layer.

Referring to FIG. 7D, the first cover insulation layer CIL1 may be formed to cover the first conductive pattern SP1. For example, the first cover insulation layer CIL1 may cover the first conductive pattern SP1 provided on the top surface of the package substrate 300 and a portion of the top surface of the package substrate 300 adjacent to the first conductive pattern SP1.

The semiconductor package 1B of FIG. 3 may be manufactured by forming the first cover insulation layer CIL1A in the process of FIG. 7D to cover both the first conductive pattern SP1 disposed on the package substrate and the first conductive pattern SP1 formed adjacent to the plurality of first semiconductor chips 110.

Referring to FIG. 7E, the plurality of second semiconductor chips 120 may be stacked and arranged on the first semiconductor chip stack C1. From among the plurality of second semiconductor chips 120, the lowermost second semiconductor chip 120B may be positioned closer to the second upper connection pad 312 than to the first upper connection pad 311 provided on the top surface of the package substrate 300. Also, the plurality of second semiconductor chips 120 may be stacked in a step-like shape as a second semiconductor chip 120 is offset in a direction away from the second upper connection pad 312 as compared to another second semiconductor chip 120 below the corresponding second semiconductor chip 120.

Referring to FIG. 7F, the first encapsulation member 210 may be formed to surround the plurality of first semiconductor chips 110 on the package substrate 300. The first encapsulation member 210 may be formed to cover a portion of the top surface of the first cover insulation layer CIL1A and to be spaced apart from the second upper connection pad 312. The first encapsulation member 210 may be formed to contact a side surface of the lowermost second semiconductor chip 120B. The first encapsulation member 210 may not be formed on the entire top surface of the package substrate 300, but may be formed spaced apart from the outer edge of the package substrate 300. The first encapsulation member 210 may be formed by limiting a region in which the first encapsulation member 210 is to be formed through a mold. In the process of forming the first encapsulation member 210 through the mold, the first cover insulation layer CIL1 may be provided, such that the first conductive pattern SP1 adjacent to the boundary of the first encapsulation member 210 is protected from the mold.

Referring to FIG. 7G, similarly to the process performed in FIG. 7B, the second side surface separating insulation layer SIL2A may be formed on the side surfaces of a plurality of second semiconductor chips 120. For example, the second side surface separating insulation layer SIL2A may be formed on the side surfaces of each of the plurality of second semiconductor chips 120 close to the second upper connection pad 312 disposed on the package substrate 300.

Referring to FIG. 7H, the second conductive pattern SP2 may be formed along the step-like shape of the plurality of second semiconductor chips 120. The second conductive pattern SP2 may extend along the top surface of each of the plurality of second semiconductor chips 120, the second side surface separating insulation layer SIL2A, the top surface of the first encapsulation member 210, the side surface of the first encapsulation member 210, and the top surface of the package substrate 300. The second conductive pattern SP2 may be connected to the second chip pad 123 disposed on the top surface of each of the plurality of second semiconductor chips 120 and the second upper connection pad 312 of the package substrate 300. For example, a second seed layer for the second conductive pattern SP2 may be second formed at a location where the second conductive pattern SP2 is to be formed, and then the second conductive pattern SP2 may be formed on the second seed layer.

Referring to FIG. 7I, the second encapsulation member 220 may be formed to surround the second semiconductor chip stack C2 and the first encapsulation member 210. The side surfaces of the second encapsulation member 220 may be aligned to the side surfaces of the package substrate 300. The top surface of the second encapsulation member 220 may be formed higher than the second semiconductor chip stack C2, such that the second encapsulation member 220 may cover the top surface of the uppermost second semiconductor chip 120T of the second semiconductor chip stack C2. Also, the external connection terminal 322 may be provided on the external connection pad 321 provided on the bottom surface of the package substrate 300. Through the manufacturing process, the semiconductor package 1 may be manufactured.

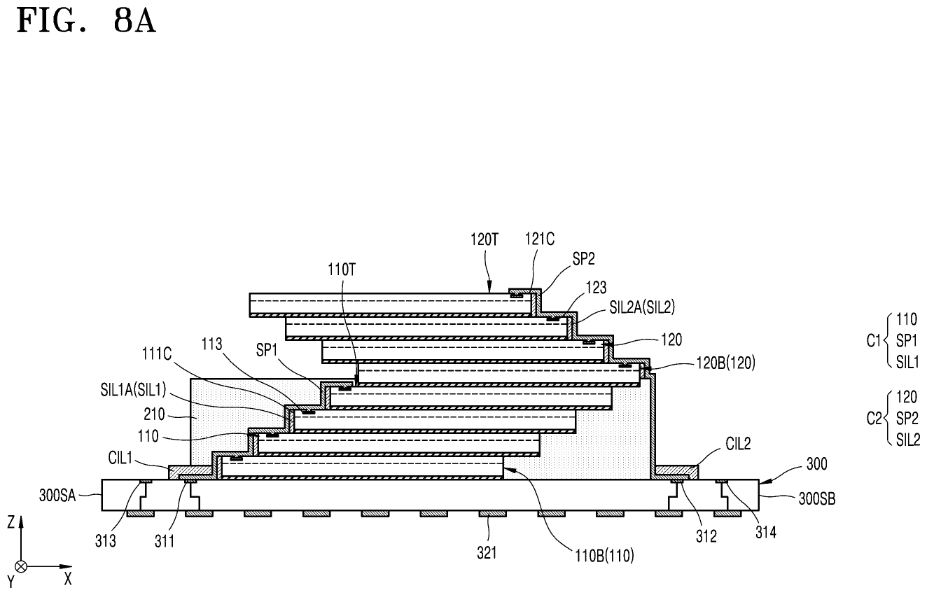

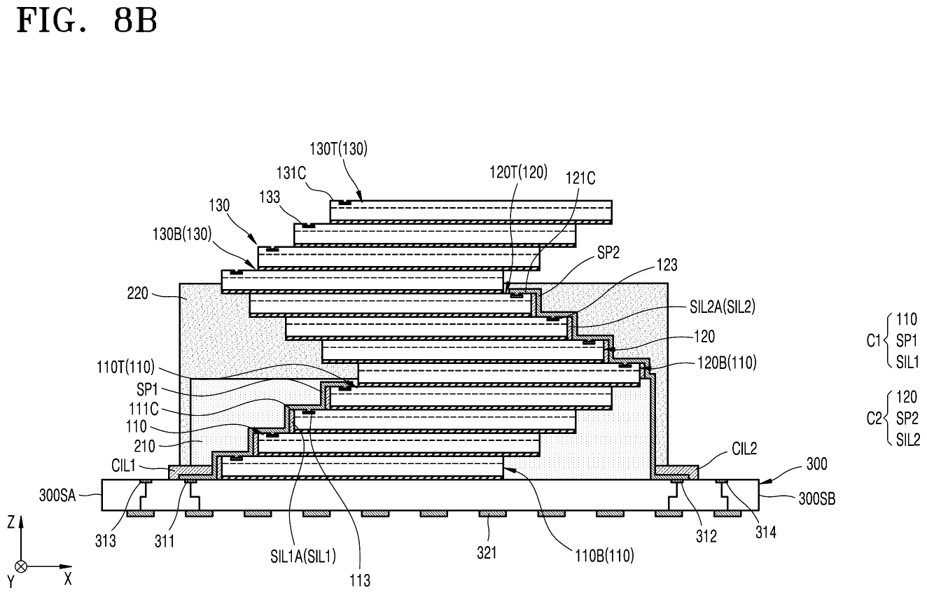

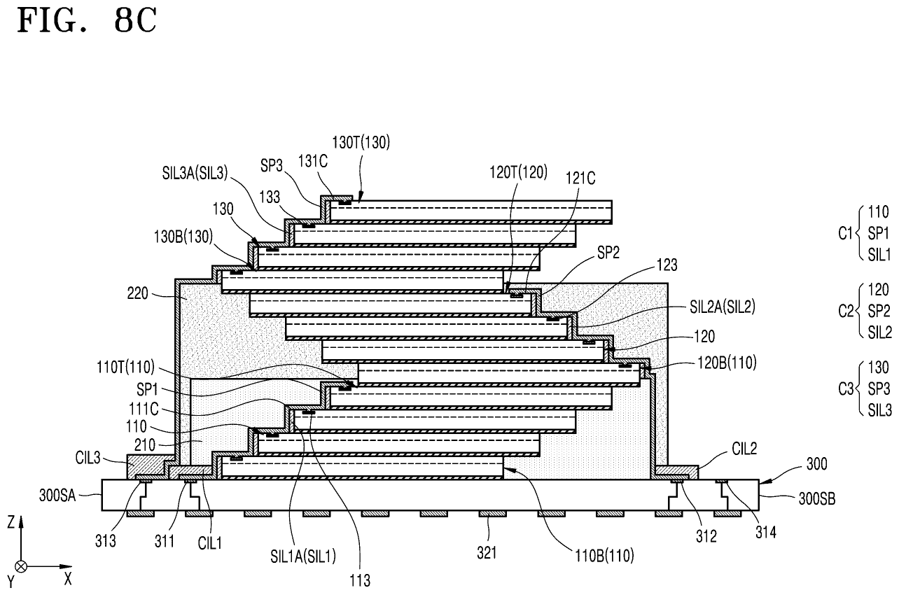

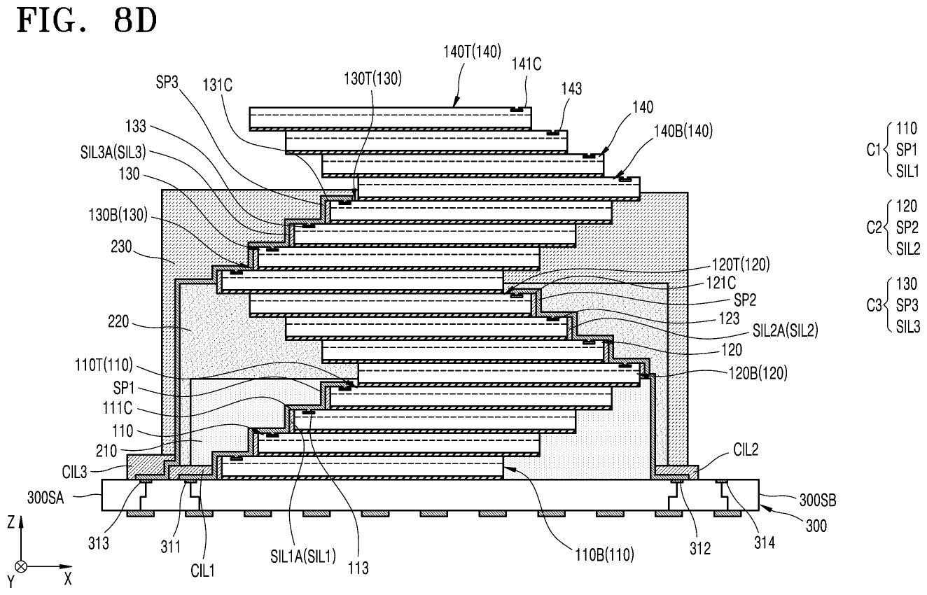

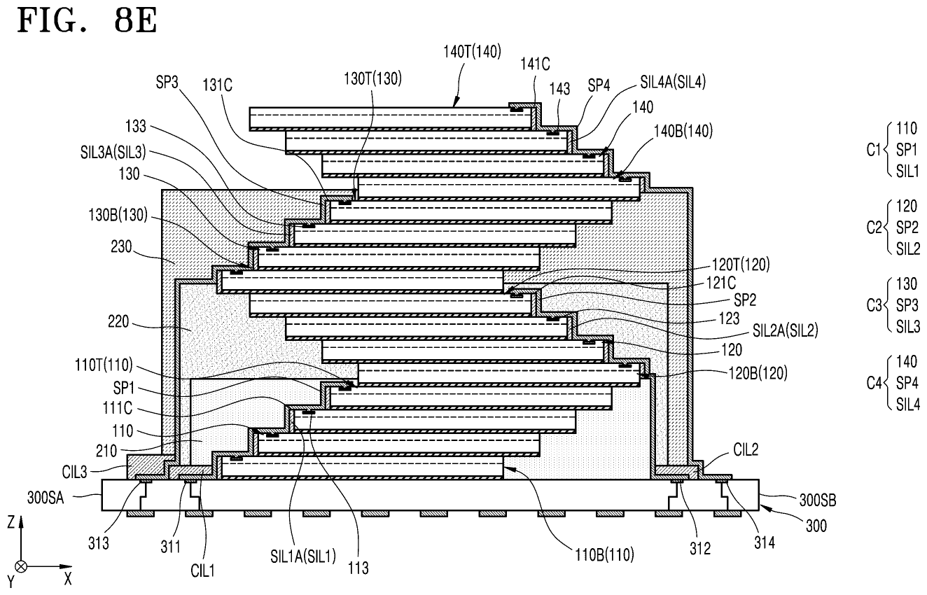

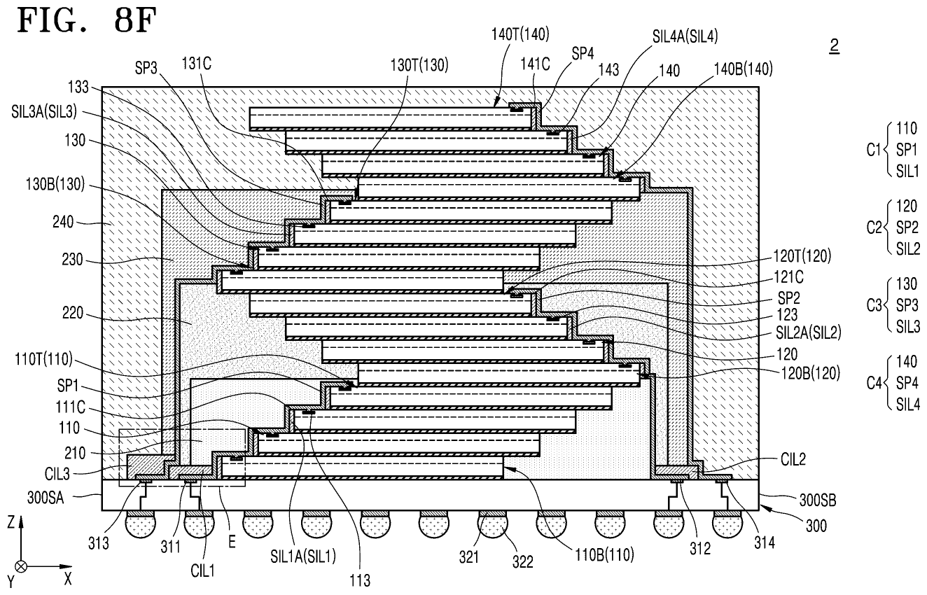

FIGS. 8A, 8B, 8C, 8D, 8E, and 8F are cross-sectional views sequentially showing an example of a process for manufacturing the semiconductor package 2. Descriptions not given below with reference to FIGS. 8A to 8F may be substantially identical to descriptions given above.

Referring to FIG. 8A, a process similar to the manufacturing process described above with reference to FIGS. 7A to 7H may be performed on the package substrate 300 including the first upper connection pad 311, the second upper connection pad 312, the third upper connection pad 313, and the fourth upper connection pad 314 and the second cover insulation layer CIL2 may be additionally formed, and thus a process result of FIG. 8A may be formed. The second cover insulation layer CIL2 may be formed to cover the second conductive pattern SP2 extending on the package substrate 300.

Referring to FIG. 8B, the plurality of third semiconductor chips 130 may be stacked in a step-like shape on the second semiconductor chip stack C2. Thereafter, the second encapsulation member 220 may be formed on the package substrate 300, such that the second encapsulation member 220 surrounds the second semiconductor chip stack C2 and the first encapsulation member 210. The second encapsulation member 220 may be formed to contact the side surfaces of the lowermost third semiconductor chip 130B. In the process of forming the second encapsulation member 220, the first cover insulation layer CIL1 may be provided on the first conductive pattern SP1 and the second cover insulation layer CIL2 may be provided on the second conductive pattern SP2, to protect the first conductive pattern SP1 and the second conductive pattern SP2 adjacent to the boundary of the second encapsulation member 220.

Similar to the first encapsulation member 210, the second encapsulation member 220 may be formed spaced apart from the outer edge of the package substrate 300, rather than being formed on the entire top surface of the package substrate 300. In the process of forming the first encapsulation member 210 by limiting a region where the second encapsulation member 220 is to be formed through the mold, the second cover insulation layer CIL2 may be provided, such that the second conductive pattern SP2 adjacent to the boundary of the second encapsulation member 220 is protected from the mold. The same applies to the third cover insulation layer CIL3 described below.

Referring to FIG. 8C, the third conductive pattern SP3 may be formed along the step-like shape of the plurality of third semiconductor chips 130. The third conductive pattern SP3 may extend along the top surface of each of the plurality of third semiconductor chips 130, the third side surface separating insulation layer SIL3A, the top surface of the second encapsulation member 220, the side surfaces of the second encapsulation member 220, the top surface and side surfaces of the first cover insulation layer CIL1, and the top surface of the package substrate 300.

The third conductive pattern SP3 may be connected to the third chip pad 133 disposed on the top surface of each of the plurality of third semiconductor chips 130 and the third upper connection pad 313 of the package substrate 300. For example, a second seed layer for the second conductive pattern SP2 may be second formed at a location where the second conductive pattern SP2 is to be formed, and then the second conductive pattern SP2 may be formed on the second seed layer.

Thereafter, the third cover insulation layer CIL3 may be formed to cover the third conductive pattern SP3 disposed on the package substrate 300 and the third conductive pattern SP3 provided adjacent to the first cover insulation layer CIL1.

Referring to FIG. 8D, the plurality of third semiconductor chips 130 may be stacked in a step-like shape on the third semiconductor chip stack C3. Thereafter, the third encapsulation member 230 may be formed on the package substrate 300, such that the third encapsulation member 230 surrounds the third semiconductor chip stack C3 and the second encapsulation member 220. The third encapsulation member 230 may be formed to contact the side surfaces of the lowermost fourth semiconductor chip 140B. In the process of forming the third encapsulation member 230, the first cover insulation layer CIL1, the second cover insulation layer CIL2, and the third cover insulation layer CIL3 may be provided to protect the first conductive pattern SP1, the second conductive pattern SP2, and the third conductive pattern SP3 adjacent to the package substrate 300.

Referring to FIG. 8E, the fourth conductive pattern SP4 may be formed along the step-like shape of the plurality of fourth semiconductor chips 140. The fourth conductive pattern SP4 may extend along the top surface of each of the plurality of fourth semiconductor chips 140, the fourth side surface separating insulation layer SIL4A, the top surface of the third encapsulation member 230, the side surfaces of the third encapsulation member 230, the top surface and the side surfaces of the second cover insulation layer CIL2, and the top surface of the package substrate 300. The fourth conductive pattern SP4 may be connected to the fourth chip pad 143 disposed on the top surface of each of the plurality of fourth semiconductor chips 140 and the fourth upper connection pad 314 of the package substrate 300.

Referring to FIG. 8F, the fourth encapsulation member 240 may be formed to surround the fourth semiconductor chip stack C4 and the third encapsulation member 230. The side surfaces of the fourth encapsulation member 240 may be aligned to the side surfaces of the package substrate 300. The top surface of the second encapsulation member 220 may be formed higher than the second semiconductor chip stack C2. The external connection terminal 322 may be provided on the external connection pad 321 provided on the bottom surface of the package substrate 300. Through the manufacturing process, the semiconductor package 2 may be manufactured.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

1. A semiconductor package comprising:
a package substrate comprising a first upper connection pad and a second upper connection pad, the first upper connection pad and the second upper connection pad being on a top surface of the package substrate;
a first semiconductor chip stack comprising a plurality of first semiconductor chips and a first chip pad, the plurality of first semiconductor chips being stacked in a step-like shape on the package substrate, the first chip pad being on a top surface of a first semiconductor chip of the plurality of first semiconductor chips;
a second semiconductor chip stack comprising a plurality of second semiconductor chips and a second chip pad, the plurality of second semiconductor chips being stacked in a step-like shape on the first semiconductor chip stack, the second chip pad being on a top surface of a second semiconductor chip of the plurality of second semiconductor chips and being closer to the second upper connection pad than to the first upper connection pad;
a first conductive pattern extending along the top surface of the first semiconductor chip, side surfaces of the first semiconductor chip, and the top surface of the package substrate, the first conductive pattern being connected with the first chip pad and the first upper connection pad;
a first cover insulation layer on the package substrate, the first cover insulation layer covering at least a portion of the first conductive pattern;
a first encapsulation member surrounding the first semiconductor chip stack and the first conductive pattern on the top surface of the package substrate; and
a second conductive pattern extending along the top surface of the second semiconductor chip, side surfaces of the second semiconductor chip, side surfaces of the first encapsulation member, and the top surface of the package substrate, the second conductive pattern being connected with the second chip pad and the second upper connection pad.

2. The semiconductor package of claim 1, comprising a first separating insulation layer on a side surface of each of the plurality of first semiconductor chips, the side surface being adjacent to the first conductive pattern.

3. The semiconductor package of claim 1, wherein the first conductive pattern comprises a first separating insulation layer spaced apart from the side surfaces of the plurality of first semiconductor chips, the first separating insulation layer being between the first conductive pattern and the side surfaces of the plurality of first semiconductor chips.

4. The semiconductor package of claim 1, wherein the first cover insulation layer covers both the first conductive pattern on the package substrate and a plurality of first conductive patterns on the plurality of first semiconductor chips.

5. The semiconductor package of claim 1, wherein a portion of the first cover insulation layer protrudes laterally from the first encapsulation member.

6. The semiconductor package of claim 1, wherein a vertical level of a top surface of the first encapsulation member is lower than a vertical level of a top surface of a lowermost second semiconductor chip and is higher than a vertical level of a bottom surface of the lowermost second semiconductor chip, the lowermost second semiconductor chip being closest to the package substrate among the plurality of second semiconductor chips of the second semiconductor chip stack.

7. The semiconductor package of claim 1, comprising a second separating insulation layer on a plurality of side surfaces of the plurality of second semiconductor chips, the plurality of side surfaces being adjacent to the second conductive pattern,
wherein a height of the second separating insulation layer on a side surface of a lowermost second semiconductor chip is less than a height of the second separating insulation layer on side surfaces of remaining second semiconductor chips of the plurality of second semiconductor chips, the lowermost second semiconductor chip being closest to the package substrate among the plurality of second semiconductor chips.

8. The semiconductor package of claim 1, comprising a second encapsulation member surrounding the plurality of second semiconductor chips, the second conductive pattern, and the first encapsulation member, wherein the first encapsulation member and the second encapsulation member are on the first cover insulation layer,
wherein a portion of the first cover insulation layer protrudes from the first encapsulation member, and
wherein the second encapsulation member is on a remaining portion of the first cover insulation layer.

9. The semiconductor package of claim 1, wherein a first adhesive layer is on a bottom surface of each of the plurality of first semiconductor chips, and
wherein the first semiconductor chip has a first active surface that is closer to the top surface of the first semiconductor chip than to a bottom surface of the first semiconductor chip.

10. The semiconductor package of claim 1, wherein the first upper connection pad and the second upper connection pad are positioned on a first side and a second side, respectively, around the first semiconductor chip stack, the first side being opposite to the second side.

11. A semiconductor package comprising:
a package substrate comprising a first upper connection pad and a second upper connection pad, the first upper connection pad and the second upper connection pad being on a top surface of the package substrate;
a first stacked chip assembly comprising a plurality of first semiconductor chips stacked in a step-like shape on the package substrate, a first chip pad on a top surface of each of the plurality of first semiconductor chips, and a first conductive pattern, the first chip pad being adjacent to a first chip edge of each of the plurality of first semiconductor chips;
a second stacked chip assembly comprising a plurality of second semiconductor chips stacked in a step-like shape on the first stacked chip assembly, a second chip pad on a top surface of each of the plurality of second semiconductor chips, and a second conductive pattern, the second chip pad being adjacent to a second chip edge of each of the plurality of second semiconductor chips; and
a first encapsulation member surrounding the first stacked chip assembly;
wherein the first conductive pattern is along top surfaces and side surfaces of the plurality of first semiconductor chips, and the first conductive pattern is connected with at least one of a plurality of first chip pads and the first upper connection pad,
wherein the second conductive pattern is along the top surfaces and the side surfaces of the plurality of first semiconductor chips and a surface of the first encapsulation member, and the second conductive pattern is connected with at least one of a plurality of second chip pads and the second upper connection pad, and
wherein a first cover insulation layer is on the top surface of the package substrate, the first cover insulation layer covering the first conductive pattern on the top surface of the package substrate.

12. The semiconductor package of claim 11, comprising:
a third stacked chip assembly comprising a plurality of third semiconductor chips stacked in a step-like shape on the second stacked chip assembly, a third chip pad on a top surface of each of the plurality of third semiconductor chips, and a third conductive pattern, the third chip pad being adjacent to a third chip edge of each of the plurality of third semiconductor chips;
a fourth stacked chip assembly comprising a plurality of fourth semiconductor chips stacked in a step-like shape on the third stacked chip assembly, a fourth chip pad on a top surface of each of the plurality of fourth semiconductor chips, and a fourth conductive pattern, the fourth chip pad being adjacent to a fourth chip edge of each of the plurality of fourth semiconductor chips;
a second encapsulation member surrounding the first encapsulation member and the second stacked chip assembly; and
a third encapsulation member surrounding the second encapsulation member and the third stacked chip assembly,
wherein the third conductive pattern is along top surfaces and side surfaces of the plurality of third semiconductor chips and a surface of the second encapsulation member, and the third conductive pattern is connected with at least one of a plurality of third chip pads and at least one of a plurality of third upper connection pads on the package substrate,
wherein the fourth conductive pattern is along top surfaces and side surfaces of the plurality of fourth semiconductor chips and a surface of the third encapsulation member, and the fourth conductive pattern is connected with at least one of a plurality of fourth chip pads and at least one of a plurality of fourth upper connection pads on the package substrate,
wherein a second cover insulation layer is on the top surface of the package substrate and covers the second conductive pattern on the top surface of the package substrate, and
wherein a third cover insulation layer is on the top surface of the package substrate and covers the third conductive pattern on the package substrate.

13. The semiconductor package of claim 12, wherein the first encapsulation member is on a first portion of the first cover insulation layer, the second encapsulation member is on a second portion of the first cover insulation layer, and the third conductive pattern is on a third portion of the first cover insulation layer,
wherein the second encapsulation member is on a first portion of the second cover insulation layer, the third encapsulation member is on a second portion of the second cover insulation layer, and the fourth conductive pattern is on a third portion of the second cover insulation layer, and
wherein the third encapsulation member is on a first portion of the third cover insulation layer.

14. The semiconductor package of claim 12, wherein the first encapsulation member is on a first portion of the first cover insulation layer, the second encapsulation member is on a second portion of the first cover insulation layer, and the first cover insulation layer and the third conductive pattern are spaced apart from each other,
wherein the second encapsulation member is on a first portion of the second cover insulation layer, the third encapsulation member is on a second portion of the second cover insulation layer, and the second cover insulation layer and the fourth conductive pattern are spaced apart from each other, and
wherein the third encapsulation member is on a first portion of the third cover insulation layer.

15. The semiconductor package of claim 12, wherein the first upper connection pad and a third upper connection pad of the plurality of third upper connection pads are on a first side, the second upper connection pad and a fourth upper connection pad of the plurality of fourth upper connection pads are on a second side, the first side being opposite to the second side around the first stacked chip assembly,
wherein the third upper connection pad is closer to an outer edge of the package substrate than the first upper connection pad is to the outer edge of the package substrate, and
wherein the fourth upper connection pad is closer to the outer edge of the package substrate than the second upper connection pad is to the outer edge of the package substrate.

16. The semiconductor package of claim 12, comprising:
a first separating insulation layer covering a first side surface of each of the plurality of first semiconductor chips, the first side surface being adjacent to the first chip edge,
a second separating insulation layer covering a second side surface of each of the plurality of second semiconductor chips, the second side surface being adjacent to the second chip edge,
a third separating insulation layer covering a third side surface of each of the plurality of third semiconductor chips, the third side surface being adjacent to the third chip edge, and
a fourth separating insulation layer covering a fourth side surface of each of the plurality of fourth semiconductor chips, the fourth side surface being adjacent to the fourth chip edge.

17. The semiconductor package of claim 12, wherein the third conductive pattern extends from a portion of a top surface and a side surface of the first cover insulation layer.

18. The semiconductor package of claim 17, wherein the fourth conductive pattern extends from a portion of a top surface and a side surface of the second cover insulation layer.

19. The semiconductor package of claim 12, comprising a fourth encapsulation member surrounding the third encapsulation member and the fourth stacked chip assembly on the top surface of the package substrate.

20. (canceled)

21. A semiconductor package comprising:
a package substrate comprising a plurality of upper connection pads on a top surface of the package substrate;
a plurality of semiconductor chip stacks, each semiconductor chip stack stacked in a step-like shape in one direction, wherein the plurality of semiconductor chip stacks are sequentially stacked in an overall zigzag shape, and two adjacent semiconductor chip stacks are stacked in different step-wise directions;
a plurality of encapsulation members on the package substrate, each encapsulation member surrounding a corresponding semiconductor chip stack among the plurality of semiconductor chip stacks; and
a plurality of conductive patterns configured to interconnect the plurality of semiconductor chip stacks and corresponding upper connection pads,
wherein the plurality of semiconductor chip stacks comprise a first semiconductor chip stack and a second semiconductor chip stack on the first semiconductor chip stack, the first semiconductor chip stack being closest to the package substrate among the plurality of semiconductor chip stacks,
wherein on the first semiconductor chip stack, the conductive pattern extends along a surface of the semiconductor chip and the top surface of the package substrate,
wherein on the second semiconductor chip stack, conductive patterns extend along the surface of the semiconductor chip, a surface of one of the plurality of encapsulation members, and the top surface of the package substrate, respectively,
wherein a separating insulation layer is between side surfaces of the plurality of semiconductor chips included in the plurality of semiconductor chip stacks and a plurality of corresponding conductive patterns,
wherein the plurality of encapsulation members comprise a first encapsulation member and a second encapsulation member,
wherein the first encapsulation member surrounds the first semiconductor chip stack, and the second encapsulation member surrounds the first semiconductor chip stack and the first encapsulation member, and
wherein a plurality of cover insulation layers respectively cover the plurality of conductive patterns and extend on the top surface of the package substrate in semiconductor chip stacks other than an uppermost semiconductor chip stack among the plurality of semiconductor chip stacks.
